(19) United States
(12) Patent Application Publication
(10) Pub. No.: US 2026/0051719 A1
(43) Pub. Date: Feb. 19, 2026

(54) VOLTAGE PRESENCE INDICATOR FOR SAFETY APPLICATION IN ELECTRICAL PANEL

(71) Applicant: PWR NUKLEUS TECHNOLOGIES PRIVATE LIMITED, Kukatpally, Hyderabad (IN)

(72) Inventors: Hardik Chandrakant KHAMBHADIYA, Makarpura, Vadodara, Gujarat (IN); Asheesh Rameshchandra DHANERIA, Makarpura, Vadodara, Gujarat (IN); Satish Hukumat CHETWANI, Makarpura, Vadodara, Gujarat (IN); Lakshmi Soujanya RAVULA, Khanamet, Hyderabad, Telangana (IN)

(21) Appl. No.: 18/854,327

(22) PCT Filed: Oct. 27, 2022
(86) PCT No.: PCT/IN2022/050950

§ 371 Date: Oct. 4, 2024

(30) Foreign Application Priority Data
Apr. 6, 2022 (IN) 202221020780

(51) Int. Cl. H02B 1/015; G08B 5/38; H05B 45/10; H05B 45/35

(52) U.S. Cl. CPC H02B 1/015; G08B 5/38; H05B 45/10; H05B 45/35

(57) ABSTRACT

The present disclosure provides a voltage presence indicator (VPI) circuit (100) for electrical safety application in electrical panel to indicate the presence of electrical potential of one or more electrical power input lines of an AC or DC circuit. The VPI circuit (100) includes plurality of voltage clipper circuits (VC1-VC5), bi-directional current limiter circuits (CL1-CL3), full bridge rectifier circuits (RC1-RC5), unbalance sensing circuits (SR1-SR2), signal conditioning circuits (S1-S2), comparator circuits (U1-U2), and flasher circuits (F1-F5). The flasher circuits (F1-F5) includes of plurality of solid state light emitting diodes (LEDs) disposed in a human viewable arrangement. The electrical circuitry of the VPI (100) converts electrical energy potential between the lines in the range of about 40 Volts to about 3000 volt into electrical inputs that drives the flasher circuit consisting of LEDs to produce light output.

### CROSS-REFERENCE TO RELATED APPLICATIONS

This application is a National Stage application of International Patent Application No. PCT/IN2022/050950, filed on Oct. 27, 2022, which claims priority to Indian Patent Application No. 202221020780, filed Apr. 6, 2022, each of which is hereby incorporated by reference in its entirety.

### TECHNICAL FIELD

The present invention generally relates to safety application in electrical field. Particularly, it relates to “voltage presence indicator for safety application in electrical panel” for monitoring and providing and/or ascertaining safety during maintenance and/or servicing work in a high voltage circuit.

### BACKGROUND

To avoid electrical hazards, to protect worker(s) and to improve worker safety during maintenance and/or servicing of electrical systems and circuits, it is highly desirable to first confirm the presence or absence of hazardous voltage in the electrical systems and circuits where maintenance or servicing work is to be performed by worker(s).

Generally, during maintenance of electrical systems and circuits carrying high voltages, a “lockout/tagout” (LOTO) procedure is performed to ensure that electrical systems and circuits or equipment therein is shut down (Turned OFF), and inoperable which allows maintenance and servicing work on the electrical system can be performed safely. Generally a disconnect switch or an isolator such as a circuit breaker or a line valve or a block or any ON/OFF switch is connected with the power supply line circuit which is turned into OFF position during servicing, and a lockout device is clamped onto the disconnect switch/isolator such as circuit breaker or similar switch using a locking device such as padlock to keep the disconnect switch/isolator such as circuit breaker in the OFF position (the “lockout”) which ensures breaking of circuit path preventing supply of high voltage current from the source supply to the servicing circuit or electrical system providing “safe mode” (de-energized mode). The purpose of this locking is to completely prevent workers from operating the disconnect switch/isolator such as circuit breaker and thus ensure non-supply of voltage to the circuit undergoing maintenance work. Further tags are used as a means of hazard communication wherein warning against activation or operation of disconnect switch/isolator (e.g. circuit breaker). The tag comprises information about the authorized person who attached the tag and lock to the system, is attached to the locked out device (the “tagout”).

Although the application of LOTO procedure prevents workers from coming into direct contact with the circuit breaker device (supply disconnect switch or isolator means) and thus minimizes any chances of power supply to the servicing circuit/system by any accident or human error. The risk to worker still exists due to presence of various hazardous current/voltages in the circuit under maintenance/servicing which is already disconnected or isolated from the source power supply lines by means of disconnect switch/isolator such as circuit breaker. Such hazardous energy may be in the form of AC or DC voltage/current which are unexpected to be present and flowing in the circuit and where workers have to perform maintenance work which is unsafe and may lead to dangerous electrical accident. Exemplary unexpected sources of DC in the circuit may be associated with capacitor such as line capacitance, bypass capacitors, or power factor correction capacitor banks. Potential unexpected sources of AC in the circuit includes generators, back-EMF of motors, or actuation of any switch associated with the supply circuit or failures of such switch associated in the circuit. Moreover, power disconnect switch/isolators or power ON/OFF switches or circuit breakers may fail to break the current flow path in the circuit leading to unknowing supply of power through the connected circuit via the locked out disconnect switch/isolator/breaker/switch increasing the risk to workers.

Use of various indicating means like meters, bulbs are known in prior art, but all suffer with many disadvantages and operation limitations in wide voltage range.

Further these conventional indicators fail to provide any information about the presence of hazard and including source of hazard. No visual indication and display is provided, and all fail to comply with OSHA 1910.147 regulation. Further operational difficulties exists leading to workplace injuries and inconvenience.

Further the conventional indicating means require opening of the electrical panel in order to imply the indicating means and check for any power supply wherein chances of getting exposed to hazardous voltages increases and hence safety cannot be assured.

In the past, other type of indicators are reported, however, they are not efficient and not flexible. A prior art patent U.S. Pat. No. 6,703,938 describes the voltage presence indicator for similar application but has demerit of limited operating voltage range which is 30 V to 750 V line to line voltage values for AC application and 30 V to 1000 V for DC application. Further in the device of the said patent, the operating voltage range cannot be flexibly adjusted.

Therefore, there is a need of an improved Voltage Presence Indicator (VPI) which is flexible, efficient and could operate in a higher voltage range, and can also be used both in downstream and upstream of a circuit.

The following contemplates an improved VPI system, device, and method thereof that overcomes the aforementioned limitations and others.

### SUMMARY

The primary object of the present invention is to provide a voltage presence indicator for safety application in an electrical panel. Accordingly, providing a voltage presence indicator (VPI) circuit, system, device, and method for the VPI for safety application in an electrical panel to ensure safety and protect workers is the main objective. The novel VPI circuit is used in the VPI system/device of the present invention.

Another object of the present invention is to develop a VPI system/device which can provide monitoring and/or flexibly operate in a wide range of stored electrical potentials.

Another object of the present invention is to develop a VPI system/device which provides monitoring any range of threshold voltages by varying the zener diode configuration for AC as well as DC voltages.

Another object of the present invention is to develop a VPI system/device which provides monitoring a range from the lowest voltage level of about 40 volts to up to about 3000 volts (line to line voltage rms values) or higher than this for AC as well as DC voltages.

Another object of the present invention is to design circuit that gives visual indication for both AC and DC voltages.

Yet another object of the present invention is to provide a VPI system/device that provides simultaneous indication of presence of voltage of all the three phases of the power line with respect to ground and/or neutral.

Another object of the present invention is to provide a VPI system/device where the visual indication for voltage presence is not directly proportional to the voltage present in the line and provides same light intensity indication for all values of the voltage present in the circuit.

Another object of the present invention is to provide a VPI system/device that can provide continuous visual indication for voltage presence for every line combination in three-phase power lines during maintenance period.

Another object of the present invention is to provide a VPI system/device for verification of electrical circuit isolation without opening or otherwise accessing the electrical panel.

Another object of the present invention is to provide a VPI system/device which consists of separate flasher circuit for better indication visibility from a distance for indication of presence of voltage in electrical power lines.

Another object of the present invention is to provide a VPI system/device where the lower voltage range (which is set as 40 V in the current invention) can be tuned to any desired value by changing the component values of electronic circuit considering the LED forward voltage drop, bridge rectifier voltage drop, voltage drop across bidirectional current limiter.

Yet another object of the present invention is to provide a VPI system/device with a flasher circuit present in the neutral and ground line to provide indication when Delta or Wye 3-Phase systems are in unbalanced state or leakage current is present in the system.

Another object of the present invention is to provide a VPI system/device where the power consumption of the voltage presence indicator circuit (VPI) can be optimized by modifying the values of resistors present in the circuit.

Another object of the present invention is to provide VPI system/device which can be applied to any type of phase circuit i.e. single phase circuit or multi phase circuit and to any desired frequency.

Another object of the present invention is to provide a method for above said VPI system/device.

Another object of the present invention is to provide a method for providing warning of a hazardous electrical voltage on a circuit using the VPI.

Another object of the present invention is to provide a method for providing detection for unbalance condition in 3 phase circuit.

Accordingly, a voltage presence indicator (VPI) for safety application in electrical panel for monitoring and providing and/or ascertaining safety during maintenance and/or servicing work in a high voltage circuit is described. A novel voltage presence indicator circuit (VPI Circuit) is provided which is used in a VPI system/device for electrical safety application of electrical panel to indicate the presence of electrical potential of one or more electrical power input lines of an AC or DC circuit. The voltage presence indicator circuit (VPI Circuit) comprises five numbers of wires which includes three line wires (referred herewith as “L1, L2, L3”), one ground wire (referred herewith as “GND”) and one neutral wire (referred herewith as “N”). Circuit of line wires (L1, L2 and L3) are similar to each other in terms of electrical connection. Circuit of ground wire (GND) and neutral wire (N) are similar to each other in terms of electrical connection. Line wire circuit includes a voltage clipper circuits, a full bridge rectifier circuit—two input wires of which are electrically connected across the voltage clipper circuit, a flasher circuit electrically connected to output wires of full bridge rectifier circuit, a bi-directional current limiter circuit electrically connected to voltage clipper circuit and one of the input wire of full bridge rectifier circuit. The other terminal of bi-directional current limiter of the line wires (L1, L2, L3) are electrically connected to each other to form a junction point. Ground (GND) and neutral wire (N) circuit includes a voltage clipper circuit, a full bridge rectifier circuit—two input wires of which are electrically connected across the voltage clipper circuit, an impedance electrically connected to the voltage clipper. The other terminal of the impedance of the neutral and ground wires (N, GND) are electrically connected to each other and also connected to the junction point of line wires. The voltage presence indicator circuit (VPI Circuit) also includes two separate set of following circuits—an unbalance sensing resistor network circuit electrically connected to line wires (L1, L2, L3), a signal conditioning circuit electrically connected to unbalance sensing resistor network circuit, a comparator circuit electrically connected to signal conditioning circuit, a flasher circuit electrically connected to comparator circuit. The output wires of full bridge rectifier circuit of neutral and ground wire are electrically connected to the supply pins of comparator circuits—with supply pins of each comparator circuit connected to power supply from one rectifier circuit.

A voltage presence indicator circuit (100) for monitoring of hazardous electrical potential of a plurality of electrical power input lines of an Alternating Current (AC) or Direct Current (DC) circuit, wherein the voltage presence indicator (100) comprises:
plurality of voltage clipper circuits (VC1-VC5) which comprises first group of voltage clipper circuits (VC1a-VC5a) and second group of voltage clipper circuits (VC1b-VC5b);
plurality of bi-directional current limiter circuits (CL1-CL3);
plurality of full-bridge rectifier circuits (RC1-RC5);
plurality of unbalance sensing resistor circuits (SR1-SR2);
plurality of signal conditioning circuits (S1-S2);
plurality of comparator circuits (U1-U2); and
plurality of flasher circuits (F1-F5).

The voltage presence indicator (100) as described above, wherein each of the plurality of the voltage clipper circuits (VC1-VC5) comprises two groups i.e. first group of voltage clipper circuits (VC1a-VC5a) and second group of voltage clipper circuits (VC1b-VC5b) wherein, the first group (VC1a-VC5a) and the second group (VC1b-VC5b) comprise plurality of zener diodes for clipping of supply voltage and provides the visual indication for presence of hazardous electrical energy potential, above a set threshold voltage value, and wherein the second group (VC1b-VC5b) of zener diodes is used to provide AC clipped voltage to the said full bridge rectifier circuits (RC1-RC5) present in all the lines L1, L2, L3, N, and GND required for flasher circuits (F1-F5) operation.

The voltage presence indicator (100) as described above, wherein the plurality of bi-directional current limiter circuits (CL1-CL3) comprises of cross coupled depletion mode MOSFET (T1-T24) where the source of each depletion mode MOSFET is coupled to the gate of the opposing MOSFET (T1-T24), and a current limiter resistor (R1-R12) is coupled between the sources of the MOSFETs, wherein the cross coupled depletion MOSFET along with current limiting resistor connected electrically in series with the zener diode group of power line wires L1, L2, and L3 to limit the current to a set level even with the application of significant high voltage and regardless of the polarity of the input supply voltage.

The voltage presence indicator (100) as described above, wherein the diode based full bridge rectifier circuits (RC1-RC3) receives clipped AC voltage from the second group (VC1b-VC3b) of zener diodes present in power lines L1, L2, and L3 for providing DC output to the flasher circuits (F1-F3) respectively, and the diode based full bridge rectifier circuits (RC4-RC5) receives clipped AC voltage from the second group (VC4b-VC5b) of zener diodes present in neutral N and ground GND wires respectively for providing DC voltage to the supply pins of comparator circuits (U1-U2) for unbalance condition detection.

The voltage presence indicator (100) as described above, wherein the unbalance sensing resistor networks (SR1 and SR2) are connected in star connection where each resistor (R15, R16, R17, R21, R22 and R23) is of high impedance and equal in value connected electrically to power line wires, wherein the function of this resistor network (SR1 and SR2) is to sense the voltage unbalance condition in the power line and provide vector sum voltage at the junction point (J2 and J3) to be processed for providing indication of unbalance condition, with the help of flasher circuit (F4 and F5) respectively.

The voltage presence indicator (100) as described above, wherein the signal conditioning circuits (S1 and S2) comprising of set resistors (R18, R24), rectifier diodes (D17, D22), capacitors (C11, C17) along with discharge resistors (R19, R25) and zener diodes (Z23, Z24), wherein the set resistor fixes the percentage unbalance voltage value at which the flasher circuit (F4, F5) gives indication for unbalance condition, rectifier diode (D17, D22) provides DC voltage needed to charge the capacitor (C11, C17), high impedance discharge resistor (R19, R25) discharges the parallel connected capacitor (C11, C17) thereby reducing the voltage available at the positive input pin of comparator (U1, U2) during the condition of restoring the balanced voltage condition from unbalanced condition, and thus making the corresponding flasher (F4 and F5) extinguished, and wherein the comparator circuit (U1 and U2) which compares the output of signal conditioning circuit (S1, S2) with its internally generated temperature compensated value for detection of unbalance condition.

The voltage presence indicator (100) as described above, wherein once the balanced condition restores from unbalanced condition, the high impedance discharge resistors (R19 and R25) placed across the capacitor (C11 and C17) present in signal conditioning circuit (S1 and S2) discharges the corresponding capacitor thereby reducing the voltage available at the positive input pin of comparator (U1 and U2) as compared to the negative input pin of the comparator, thus making the LEDs of flasher circuit (F4 and F5) extinguished.

The voltage presence indicator (100) as described above, wherein the voltage rating and the number of zener diodes in the circuit (100) are set based on the required value of threshold voltage at which the voltage presence indicator circuit (100) starts giving indication for the presence of electrical energy potential.

The voltage presence indicator (100) as described above, wherein in place of the first group (VC1a-VC5a) and the second group (VC1b-VC5b) of zener diodes of the voltage clipper circuit (VC1-VC5) in a particular wire of voltage presence indicator circuit (100), a single rating of zener diode can be selected to perform the function of both the groups—first group and second group zener diodes.

The voltage presence indicator (100) as described above, wherein the operation range of the voltage presence indicating circuit (100) can be extended to a particular desired voltage range by modifying the number and/or rating of cross coupled depletion mode devices i.e. depletion MOSFET along with current limiting resistor or by varying the voltage rating of the zener diode of voltage clipper circuits (VC1-VC5), wherein the lower value of operational voltage range i.e. the detection threshold voltage is configured by varying the voltage ratings of zener diodes of voltage clipper circuit and the higher value is configured by varying the rating and/or the number of cross coupled depletion MOSFET.

The voltage presence indicator (100) as described above, wherein the full bridge diode rectifier circuit (RC1-RC5) which receives the clipped AC voltage from the second group of zener diode (VC1b-VC5b) for the full range of input voltage operation, the zener diodes are connected in common cathode configuration for operation of flasher circuits (F1-F5).

The voltage presence indicator (100) as described above, wherein the bidirectional current limiters (CL1-CL3) placed in lines L1, L2 and L3 can be placed suitably in N and GND wire lines making the main circuit symmetrical in terms of placement of components in line wires (L1, L2, and L3) and neutral wire (N) and ground wire (GND).

The voltage presence indicator (100) as described above, wherein the power consumption of voltage presence indicator circuit (100) is optimized by modifying the values of current limiting resistors (R1-R12) connected between the source terminals of cross coupled depletion MOSFETs and modifying the resistor values present in unbalance sensing resistor network SR1 (R15-R17) and SR2 (R21-R23).

The voltage presence indicator (100) as described above, wherein an opto-coupler including an opto-coupler input is electrically arranged in place of LEDs of flasher circuit to produce optically isolated signals for isolated remote monitoring.

The voltage presence indicator (100) as described above, wherein the illumination intensity of the LEDs of the flasher circuits (F1-F5) are not directly proportional to the voltage present in the line i.e. the provided LEDs illuminate with same intensity of light for any value of the operational voltage range present in the line.

The voltage presence indicator (100) as described above, wherein the voltage presence indicator (100) is applied to different type of sources i.e. AC as well as DC, different type of phase circuits i.e. single phase circuit or multi phase circuit and to different frequencies.

The voltage presence indicator (100) as described above, wherein the electrical circuitry of the voltage presence indicator (100) converts electrical energy potential between the lines in the range of about 40 Volts to about 3000 volt into electrical inputs that drives the flasher circuit consisting of LEDs to produce light output.

The voltage presence indicator (100) as described above, wherein the plurality of electrical power input lines of an Alternating Current (AC) or Direct Current (DC) circuit comprises L1, L2, L3, Neutral (N) and Ground (GND).

A method for providing warning of a hazardous electrical voltage on a circuit, the method including: arranging plurality of high impedance bi-directional current path (CL) in which cross coupled depletion MOSFETs offers variable impedance based on the applied input voltage, wherein clipped AC voltage across the common cathode configured zener diode provides clipped AC voltage to the rectifier circuit needed for the operation of flasher circuit which drives LEDs, for the whole operational input voltage range.

The method as described above, wherein the method further comprises: limiting the current flowing in a high impedance path irrespective of the magnitude of hazardous electrical voltage.

A method for providing detection for unbalance condition in a three-phase circuit, wherein the method comprises: a set of resistor network (SR1-SR2) connected in star connection along with signal conditioning circuits (S1-S2), comparator circuits (U1-U2) wherein comparator circuits (U1-U2) receives DC voltage for its operation from the full bridge rectifier circuits (RC4-RC5) connected to the second group (VC4b-VC5b) of zener diodes present in neutral or ground wire.

The method as described above, wherein the method further comprises: the set of second group (VC4b-VC5b) of zener diodes which provides clipped AC voltage to the full bridge rectifier (RC4-RC5) present in the neutral (N) and ground (GND) wires are connected electrically to the neutral (N) and ground (GND) terminal of the circuit.

A voltage presence indicator (100) for providing warning of a hazardous electrical voltage on a circuit powered by a plurality of electrical power input lines, wherein the voltage presence indicator (100) comprises:
a. plurality of high impedance bi-directional current paths where plurality of cross coupled depletion MOSFETs (T1-T24) offers variable impedance based on the applied input voltage wherein AC clipped voltage across the common cathode configured zener diode provides constant clipped AC voltage needed for the operation of flasher circuit which drives LEDs, for the whole operational input voltage range;
b. plurality of rectifying paths in which a part of main circuit component current flows through the branch circuit comprising of full bridge rectifier circuits (RC1-RC5) and filter capacitors associated with full bridge rectifier circuits (RC1-RC5);
c. plurality of sensing resistor network (SR1-SR2) comprising equal value and high impedances connected in star fashion wherein each set resistors (R15, R16, R17, R21, R22, R23) of the sensing resistor network (SR1 and SR2) is communicating with the phase lines to sense the unbalance condition;
d. plurality of signal conditioning circuits (S1-S2) which processes the voltage at the junction points (J2 and J3) of sensing resistor network (SR1-SR2) to provide signal voltage to the comparator (U1-U2) to trigger flasher circuit (F4, F5) of neutral (N) or ground (GND) wire; and
e. plurality of high impedance discharge resistors (R19, R25) placed across the capacitor (C11, C17) present in signal conditioning circuit (S1, S2) which discharges the parallel connected capacitor and helps in reducing the voltage available at the positive input pin of comparator during the condition of restoring the balanced voltage condition from unbalanced condition, thus making the corresponding flasher extinguished;
wherein, the set resistor connected at the junction point of sensing resistor network to tune the percentage unbalance voltage value at which the flasher circuit starts giving indication for unbalance condition.

The voltage presence indicator (100) as described above, wherein the main circuit components comprise of voltage clipper circuit which includes zener didoes and bi-directional current limiter circuit which includes depletion MOSFETs.

The voltage presence indicator (100) as described above, wherein plurality of electrical power lines comprises a three phase lines (L1, L2 and L3), a ground (GND) line and a neutral (N) line, the current in the main circuit components flows between three phase lines (L1, L2 and L3) in normal balanced condition and the current flows through ground (GND) and neutral (N) wire in unbalanced condition.

The voltage presence indicator (100) as described above, wherein plurality of electrical power lines comprises three phase lines (L1′, L2′ and L3′) and a ground (GND′) line, the current in the main circuit components flows between three phase lines (L1′, L2′ and L3′) in normal balanced condition and the current flows through ground (GND′) in unbalanced condition.

The voltage presence indicator (100) as described above, wherein plurality of electrical power lines comprises a single phase line (L″), a neutral line (N″) and a ground (GND″) line, the current in the main circuit components flows from single phase line (L″) to ground (GND″) and neutral (N″) wires.

The voltage presence indicator (100) as described above, wherein plurality of electrical power lines comprises two differential AC lines (L1′″ and L2′″), a neutral line (N″) and a ground (GND′″) line, the current in the main circuit components flows from two differential AC lines (L1′″ and L2′″) to ground (GND′″) and neutral (N′″) wires.

The voltage presence indicator as described above, wherein plurality of electrical power lines comprises two wire (L1″″, L2″″) DC system, the current in the main circuit components flows from positive power line (L1″″) to negative power line (L2″″).

The voltage presence indicator (100) as described above, wherein plurality of electrical power lines comprises two wires (L1′″″ and L2′″″) DC system and a ground line (GND), the current in the main circuit components flows from positive (L1′″″) and negative (L2′″″) power line to ground (GND).

The voltage presence indicator (100) described above, wherein the plurality of electrical power input lines may include both ground (GND) and neutral (N) lines or may include any of a ground (GND) or neutral (N) line.

The voltage presence indicator (100) as described above, wherein the flasher circuits present in each line wire starts giving indication for the presence of voltage in the phase lines, once the input applied voltage is greater than the set threshold voltage.

The voltage presence indicator (100) as described above, wherein the said voltage presence indicator (100) can be modified to incorporate solid ON indication by placing the LEDs in series with the cross coupled depletion mode devices along with suitable resistor in series and by eliminating the flasher circuit.

The voltage presence indicator (100) as described above, wherein the voltage presence indicator circuitry (100) is placed in an isolation module and kept inside the panel box (13) and only the light indication module (100.1) is brought to the door (14) of panel box (13) by using a fiber optic cable (21) or other methods, or is placed in a direct attachment without cable connection and isolation module.

The voltage presence indicator (100) as described above, wherein the voltage presence indicator (100) comprises a feature of external dry contacts using opto coupler to trigger any external circuits such as Programmable Logic Controller (PLC)/Supervisory Control and Data Acquisition (SCADA).

The voltage presence indicator (100) as described above, wherein the voltage presence indicator (100) comprises a current limited test points (11) at the door (14) to measure the voltage using a portable test instrument.

The voltage presence indicator and method and functions as described above, as shown in figures and further as described in detail description.

### BRIEF DESCRIPTION OF THE DRAWINGS

The foregoing and other features of the present invention will become more apparent from the following detailed description of various aspects and embodiments of the present invention read in conjunction with the accompanying drawings which are part of the specification of the present invention. In the description below, the VPI circuit and the VPI system and device prepared using the VPI circuit are described and elaborated with reference to representative drawing figures, wherein reference numerals are set forth in drawings figures to provide a thorough understanding of the embodiments of the invention, in which:

FIG. 1: Shows an electrical schematic of a three-phase star connected, five-wires (L1, L2, L3, N, GND) electrical power circuit (200) under maintenance, in conjunction with a voltage presence indicator circuit (100) of present invention.

FIG. 2: Shows a block diagram of the voltage presence indicator circuit (100) of FIG.—1 used in the VPI system/device of present invention.

FIG. 3: Shows a schematic representation of electrical circuitry of the voltage presence indicator circuit (100) of FIGS. 1-2.

FIGS. 3A-3E: Show enlarged view of portions circuitry of FIG. 3 showing various electrical components used in the VPI circuit (100), wherein
3A and 3C show plurality of voltage clipper circuits (VC1-VC5),
3B shows plurality of bi-directional current limiter circuits (CL1-CL3),
3D shows a full-bridge rectifier circuit (RC1) and a flasher circuit (F1);
3E shows a plurality of unbalance sensing circuits (SR1-SR2); plurality of signal conditioning circuits (S1-S2); and plurality of comparator circuits (U1-U2).

FIG. 4: Shows an electrical schematic of a three-phase delta connected, four-wires (L1′, L2′, L3′ and GND′) electrical power circuit (200′) under maintenance, in conjunction with voltage presence indicator circuit (100′) of present invention.

FIG. 5: Shows an electrical schematic of a single-phase two wires (L1″, and N″) electrical power circuit (200″) under maintenance, in conjunction with voltage presence indicator circuit (100″) of present invention.

FIG. 6: Shows an electrical schematic of a single-phase three-wires (L1′″, L2′″ and N′″) electrical power circuit (200′″) under maintenance, in conjunction with voltage presence indicator circuit (100′″) of present invention.

FIG. 7: Shows an electrical schematic of a DC single source, two-wires (L1″″ and L2″″) electrical power circuit (200″″) under maintenance, in conjunction with voltage presence indicator circuit (100″″).

FIG. 8: Shows an electrical schematic of a DC single source, two-wires (L1′″″ and L2′″″) with ground (GND, safety application) electrical power circuit (200′″″) under maintenance, in conjunction with voltage presence indicator circuit (100′″″) of present invention.

FIG. 9A-9B: Show visual display module (100.1) with LEDs for indication of the VPI system/device, wherein

FIG. 9A: Circular display model of visual module of one embodiment.
FIG. 9B: Polygonal display model of visual module of one embodiment.

FIG. 10: Shows mounting assembly and/or system of VPI system/device in an electrical panel, wherein

FIG. 10A: Shows a mounting system where complete VPI system/device is mounted on the opening door (14) of an electrical panel box (13), in one example embodiment.
FIG. 10B: Shows a mounting system where only visual display module (100.1) of VPI system/device is mounted in the opening door (14) of an electrical panel box (13) wherein the VPI circuit module (100.2) is separately mounted/placed inside the panel box (13) and connected with the visual display module via cable, in one example embodiment.

FIG. 11: Shows mounting mechanism for fixing VPI system/device in the door (14) of electrical panel box (13), in one example embodiment.

However, the above drawings should not be considered as limiting the invention. The drawings are non-limiting and are only for the purpose of illustration. Different forms and variations in the invention described are within the scope of the present invention.

### DETAILED DESCRIPTION

The present invention provides and describes voltage presence indicator for safety application in electrical panel for monitoring and providing and/or ascertaining safety during maintenance and/or servicing work in a high voltage circuit. Accordingly, a Voltage Presence Indicator circuit (VPI circuit) is provided which is used in the Voltage Presence Indicator (VPI) system, device, and method for safety application in electrical panel of an electrical circuit. The VPI system, device, and method identifies and detects electrical hazards for unsafe voltages, and provides indication for a safe electrical disconnection and isolation, and further ensures worker safety in electrical operations.

In one aspect, the invention provides a Voltage Presence Indicator circuit (VPI circuit).

In another aspect, the invention provides a Voltage Presence Indicator system/device (VPI system/device) utilizing the above said VPI circuit.

In some embodiments, the above said Voltage Presence Indicator circuit (VPI circuit) and Voltage Presence Indicator system/device (VPI system/device) utilizing the above said VPI circuit are referred by same numeral (100).

In other aspects, the invention further provides methods for the VPI circuit and the VPI system/device of the present invention.

In one embodiment, the voltage presence indicator circuit (100) for electrical safety application of electrical panel to indicate the presence of electrical potential of one or more electrical power input lines of an alternating current (AC) or direct current (DC) circuit. The VPI circuit and the system and/or device using same may be applied in a multi-phase circuit or a single-phase circuit or DC circuit. Further, the VPI circuit and the system and/or device of the present invention can be applied to any frequency. In one embodiment, the VPI is applied in a three-phase circuit. In one embodiment, the VPI is applied in a single-phase circuit.

The voltage presence indicator circuit (100) comprises plurality of:
voltage clipper circuits (for example VC1-VC5) comprising of a first group of voltage clipper circuits (VC1a-VC5a) and a second group of voltage clipper circuits (VC1b-VC5b),
full bridge rectifier circuits (for example RC1-RC5),
bi-directional current limiter circuits (for example CL1-CL3),
unbalance sensing resistor circuits (for example SR1-SR2),
signal conditioning circuits (for example S1-S2),
comparator circuits (for example U1-U2) and
flasher circuits (for example F1-F5).

Flasher circuits F1, F2 and F3 provide the indication for presence of voltage in the power lines (L1, L2, L3). Flashers F4 and F5 provide indication for unbalance voltage present in the power lines. Each of the flasher circuits (F1-F5) comprises of plurality of solid state light emitting diodes (LEDs) provided in an arrangement such that the light indications of LEDs can be viewable by worker/technicians. This electrical circuit communicates with plurality of electrical lines (L1, L2, L3, N, GND) of the panel to determine the presence of electrical potential in the line and the plurality of LEDs give indication for the presence of electrical energy potential. The LEDs gives indication by illumination. In one embodiment, the illumination intensity of the LEDs are not directly proportional to the voltage present in the line i.e. the provided LEDs illuminate at same intensity of light for any value of the voltage present in the line.

As mentioned above, the voltage presence indicator circuit (100) consists of separate flasher circuits (F1, F2, F3) for indication of presence of voltage of corresponding electrical power line (L1, L2, L3) respectively. The flasher circuits (F4, F5) present in the neutral (N) and ground (GND) line respectively provide indication when Delta or Wye 3-Phase systems are in unbalanced state or leakage current is present in the system.

Voltage presence indicator circuit (100) includes five numbers of wires, wherein three wires are called as line wires namely L1, L2, L3; one is called ground wire namely GND; and one neutral wire namely N. Circuits of line wires (L1, L2 and L3) are similar to each other in terms of electrical connection. Circuits of ground and neutral wires are similar to each other in terms of electrical connection.

Following circuit of voltage presence indicator circuit (100) is referred as main circuit:
1. the voltage clipper circuits (VC1-VC3) comprising of the first group of voltage clipper circuits (VC1a-VC3a) and the second group of voltage clipper circuits (VC1b-VC3b), the full bridge rectifier circuits (RC1-RC3), the flasher circuits (F1-F3) and the bidirectional current limiter circuits (CL1-CL3) present in each power line (L1, L2 and L3); and
2. the voltage clipper circuits (VC4-VC5) comprising of the first group of voltage clipper circuits (VC4a-VC5a) and the second group of voltage clipper circuits (VC4b-VC5b), present in neutral wire (N) and ground wire (GND).

In addition to main circuit, the voltage presence indicator circuit (100) also comprises of following two sets of unbalance detection circuits with each set of unbalance detection circuit associated with neutral wire (N) and ground wire (GND):
1. First set of unbalance detection circuit: which comprises a first unbalance sensing resistor network circuit (SR1), a first signal conditioning circuit (S1), a first comparator circuit (U1), a flasher circuit (F4) and a full bridge diode rectifier circuit (RC4).
2. Second set of unbalance detection circuit: which comprises a second unbalance sensing resistor network circuit (SR2), a second signal conditioning circuit (S2), a second comparator circuit (U2), a flasher circuit (F5) and a full bridge diode rectifier circuit (RC5).

The output wires of full bridge rectifier circuits (RC4, RC5) of neutral (N) and ground (GND) wires respectively are electrically connected to the supply pins of comparator circuits (U1 and U2) respectively.

Further, the electrical circuitry of the voltage presence indicator (100) converts any value electrical energy potential into electrical inputs that drives the flasher circuit consisting of LEDs to produce light output. As an example, in one embodiment of the present invention, the voltage presence indicator (100) converts electrical energy potential between the lines in the range of about 40 Volts to about 3000 volts into electrical inputs that drives the flasher circuit consisting of LEDs to produce light output.

The said Voltage Presence Indicator monitors a wide range of stored electrical potentials based upon the rating of the components. Further, as an example in the present invention, the present invention provides a monitoring range from the lowest voltage level of 40 volts to up to 3000 volts (line to line rms values) based upon the ratings of the component used and gives visual indication for both AC and DC voltages.

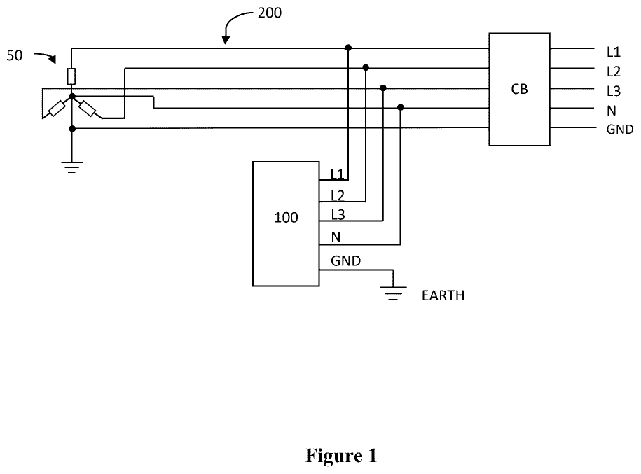

Now referring to the figures of the present invention, FIG. 1 shows a circuit (200) on which maintenance or service work is to be carried out and therein to ensure safety of workers by protecting them from any hazardous voltage (AC/DC), presence or absence of such hazardous voltage need to be checked and verified, even after disconnecting the load from the supply lines by using a disconnect switch/isolator means such as circuit breaker (CB) or any switch for similar purpose. As shown in FIG. 1, the circuit (200) includes a Wye connected three phase load (50) connected to lines L1, L2, L3 by three phase power with respect to ground potential (GND). The junction of the three phases in Wye connection forms the neutral (N) and is grounded. As represented in the figure, the circuit (200) comprises circuit breaker (CB) as a disconnect switch/isolator means which is provided to connect or disconnect the three phase power supply line from the load (50). Wherein when CB is OFF, the three lines are disconnected with the load (50) and when CB is ON, the three lines are connected with the load (50). When the CB is OFF, the three lines L1, L2, L3 downstream the CB are assumed to be electrically isolated and disconnected having zero potential in the downstream lines. At this point, the circuit (200) is not expected to comprise any voltage (AC/DC) as CB has totally disconnected the supply lines and hence no voltage is expected to be present downstream the CB, and therefore the circuit (200) should be safe for worker to carry out maintenance work at load (50).

However, there are many chances and/or circumstances wherein even after the power supply is disconnected to the load via turning the CB “OFF”, presence or absence of any hazardous voltage potential in the lines cannot be verified/confirmed and thus safety cannot be assured to workers by the isolation of CB only.

Unexpectedly, there may be chances of presence of hazardous voltage in the connected lines. Examples of such potential unexpected sources of hazardous voltage may be DC or AC which may include one or more of line capacitance, bypass capacitors, or power factor correction capacitor banks, standby power generators, motor back-EMF, or human operation of an associated switch, which may remain present in between any two of the lines (L1, L2, and L3) or between one or more line with respect to neutral (N) and/or ground (GND). To verify whether any hazardous voltage is present or absent in the downstream after turning the CB to OFF position, there need to be performed a further test of voltage presence in these downstream lines. One such test can be conveniently completed by employing a voltage presence indicator circuit (VPI circuit) comprising LED lights which can detect and indicate presence of voltage by illumination of LED lights (Flashing/Solid-on).

The present invention provides a novel VPI circuit (100) (FIG. 1) which is flexible and can operate in a wide voltage range that can be connected to the various lines coming from circuit breaker (CB) and thus used in conjunction with the above circuit (200) to check and verify presence of any hazardous voltage even after turning OFF the CB, and thus ensure worker's safety.

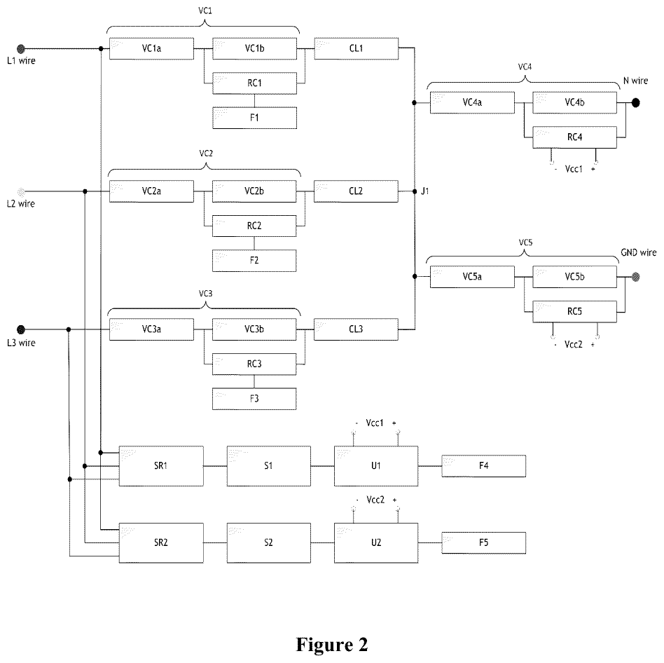

FIG. 2 shows the block diagram of voltage presence indicator circuit (100) of FIG.—1. Referring to FIG. 2, the VPI circuit (100) connected to lines downstream the CB comprises of two separate circuits, one for the line wires (L1, L2, L3), and the other for ground and neutral (GND, N) wires. The circuit of line wires (L1, L2 and L3) are similar to each other in terms of component values and their electrical connection, and the circuit of ground (GND) and neutral (N) wires are similar to each other in terms of component values and their electrical connection.

In one example embodiment of the present invention, the voltage presence indicator circuit (100) includes plurality of following circuits:
five voltage clipper circuits (VC) viz. VC1, VC2, VC3, VC4, and VC5;
five full bridge rectifier circuits (RC) viz. RC1, RC2, RC3, RC4, and RC5;
three bi-directional current limiter circuits (CL) viz. CL1, CL2, and CL3;
two unbalance sensing resistor circuits (SR) viz. SR1, and SR2;
two signal conditioning circuits (S) viz. S1, and S2;
two comparator circuits (U) viz. U1, and U2; and
five flasher circuits (F) viz. F1, F2, F3, F4, and F5.

The line wire (L1) circuit includes voltage clipper circuit (VC1), full bridge rectifier circuit (RC1), Bi-directional current limiter circuit (CL1) and flasher circuit (F1).

The line wire (L2) circuit includes voltage clipper circuit (VC2), full bridge rectifier circuit (RC2), Bi-directional current limiter circuit (CL2) and flasher circuit (F2).

The line wire (L3) circuit includes voltage clipper circuit (VC3), full bridge rectifier circuit (RC3), Bi-directional current limiter circuit (CL3) and flasher circuit (F3).

The neutral wire (N) circuit includes voltage clipper circuit (VC4).

The ground wire (GND) circuit includes voltage clipper circuit (VC5).

Each of the said voltage clipper circuits VC1-VC5 has been divided into two groups such that
A first group of voltage clipper circuits (VC1a-VC5a) comprises of zener diodes (Z1, Z2), (Z5, Z6), (Z9,Z10), (Z15,Z16) (Z19,Z20) respectively; and
A second group voltage clipper circuits (VC1b-VC5b) comprises of Zener diodes (Z3, Z4), (Z7, Z8), (Z11, Z12), (Z13, Z14), (Z17,Z18) respectively.

In another embodiment of the present invention, in place of first group (VC1a-VC5a) and second group (VC1b-VC5b) of zener diodes of the voltage clipper circuit (VC1-VC5) in a particular wire of voltage presence indicator circuit (100), a single rating of zener diode is selected to perform the function of both the groups—first group and second group zener diodes.

Now here, the detailed elaboration of line L1 is presented. The circuits of Line L2 and L3 are similar to that of L1. Now, considering the circuit of only line L1, as mentioned above the voltage clipper circuit (VC1) has been divided into two groups i.e. first group (VC1a) of voltage clipper circuit (VC1) and second group (VC1b) of voltage clipper circuit (VC1). One terminal of first group (VC1a) of voltage clipper circuit (VC1) is electrically connected to L1 wire of voltage presence indicator circuit. The other terminal of first group (VC1a) of voltage clipper circuit (VC1) is electrically connected to one terminal of second group (VC1b) of voltage clipper circuit (VC1). The other terminal of second group (VC1b) of voltage clipper circuit (VC1) is electrically connected to the one terminal of bi-directional current limiter (CL1). The circuit further comprises of a full bridge diode rectifier (RC1), the two input wires of which are electrically connected across the second group (VC1b) of voltage clipper circuit (VC1). The flasher circuit (F1) is electrically connected to output wires of full bridge diode rectifier (RC1). In the similar way, the line circuits of lines (L2 and L3) are connected. The other terminal of bi-directional current limiter of the line wires (L1, L2, L3) are electrically connected to each other to form a junction point (J1).

The voltage presence indicator circuit (100) further comprises two separate sets of following circuits:
an unbalance sensing resistor network circuit (SR1) electrically connected to line wires (L1, L2, L3), a signal conditioning circuit (S1) electrically connected to unbalance sensing resistor network circuits (SR1), a comparator circuits (U1) electrically connected to signal conditioning circuits (S1) and a flasher circuit (F4) electrically connected to comparator circuit (U1) and a full bridge diode rectifier circuit (RC4) which is electrically connected to second group of voltage clipper circuit (VC4b) present in neutral wire (N); and
an unbalance sensing resistor network circuit (SR2) electrically connected to line wires (L1, L2, L3), a signal conditioning circuit (S2) electrically connected to unbalance sensing resistor network circuits (SR2), a comparator circuits (U2) electrically connected to signal conditioning circuits (S2) and a flasher circuit (F5) electrically connected to comparator circuit (U2) and a full bridge diode rectifier circuit (RC5) which is electrically connected to second group of voltage clipper circuit (VC5b) present in ground wire (GND).

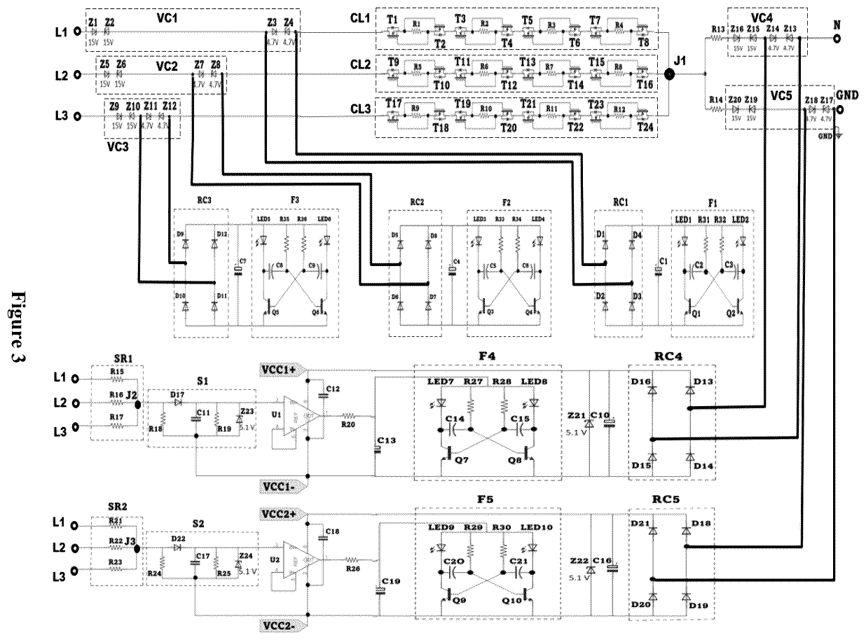

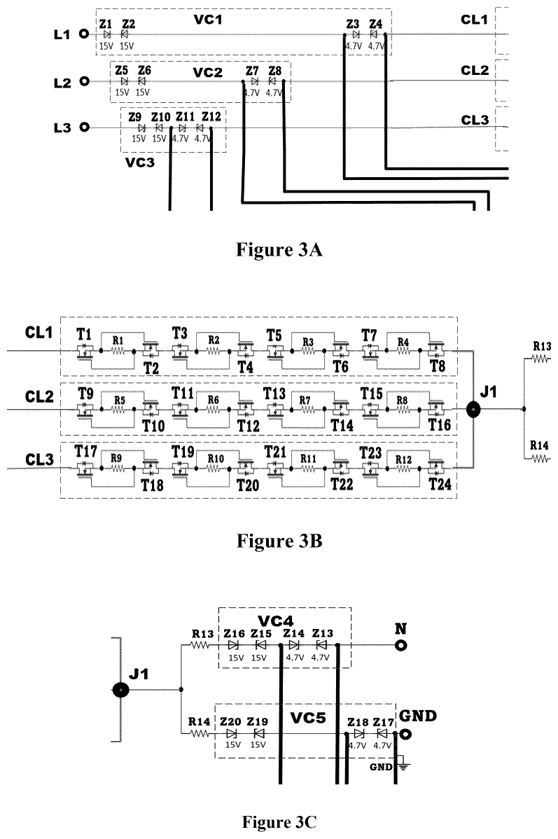

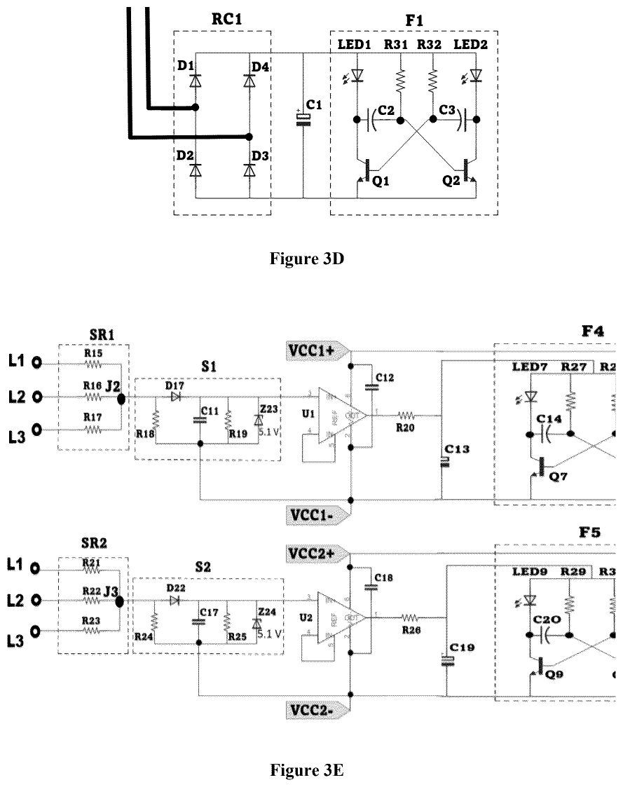

Now here, the detailed elaboration of neutral wire (N) circuit is presented. The circuit of ground wire (GND) is similar to that of neutral wire (N). Now, considering the circuit of only neutral wire (N), as mentioned above the voltage clipper circuit (VC4) has been divided into two groups i.e. first group (VC4a) of voltage clipper circuit (VC4) and second group (VC4b) of voltage clipper circuit (VC4). One terminal of second group (VC4b) of voltage clipper circuit (VC4) is electrically connected to neutral wire (N) of voltage presence indicator circuit, and the other terminal of second group (VC4b) of voltage clipper circuit (VC4) is electrically connected to one terminal of first group (VC4a) of voltage clipper circuit (VC4). The other terminal of first group (VC4a) of voltage clipper circuit (VC4) is electrically connected to one terminal of an impedance. The circuit further comprises of a full bridge diode rectifier (RC4), two input wires of which are electrically connected across the second group (VC4b) of voltage clipper circuit (VC4). The output wires of full bridge rectifier circuit of neutral wire are electrically connected to the supply pins of comparator circuit (U1). In the similar way, the line circuit of ground wire (GND) is also connected as shown in FIG. 3. The other terminal of the impedance of the neutral and ground wire (N, GND) are electrically connected to each other and also connected to the junction point (J1).

FIG. 3 shows the complete electrical schematic of circuitry of the voltage presence indicator circuit (100) which is connected to the electrical lines (L1, L2, L3, N and GND) of the electrical panel in FIG. 1. FIGS. 3A-3E show enlarged view of portions circuitry of FIG. 3 showing various electrical components present in the VPI circuit (100), wherein 3A and 3C show plurality of voltage clipper circuits (VC1-VC5), 3B shows plurality of bi-directional current limiter circuits (CL1-CL3), 3D shows a full-bridge rectifier circuit (RC1) and a flasher circuit (F1); 3E shows a plurality of unbalance sensing circuits (SR1-SR2); plurality of signal conditioning circuits (S1-S2); and plurality of comparator circuits (U1-U2). The following descriptions are with reference to FIG. 3 and FIGS. 3A-3E.

This circuit (100) monitors the presence of hazardous voltage present in the lines. The circuit (100) includes zener diodes Z1, Z2, Z3, Z4, Z5, Z6, Z7, Z8, Z9, Z10, Z11, Z12, Z13, Z14, Z15, Z16, Z17, Z18, Z19, Z20 which acts as voltage clipper circuit (VC1-VC5) for all line wires (L1, L2 and L3) and neutral (N) and ground (GND) wires in such a way that Z1-Z4 correspond to VC1, Z5-Z8 correspond to VC2, Z9-Z12 correspond to VC3, Z13-Z16 correspond to VC4 and Z17-Z20 correspond to VC5. Following zener diodes provide clipped AC input voltage to the various full bridge diode rectifier circuit (RC1-RC5) for the whole input voltage range (Z3 and Z4 for RC1), (Z7 and Z8 for RC2), (Z11 and Z12 for RC3),(Z13 and Z14 for RC4) and (Z17 and Z18 for RC5). The voltage rating and number of zener diodes in the circuit can be set based on the required value of threshold voltage at which the voltage presence indicator circuit (100) starts detecting the presence of electrical energy potential present in the lines.

Set of diodes (D1, D2, D3, D4), (D5, D6, D7, D8), (D9, D10, D11, D12) are connected to form full bridge rectifier circuits (RC1, RC2 and RC3 respectively) and receives clipped (regulated) supply from the set of zener diodes (Z3, Z4), (Z7, Z8), (Z11, Z12) respectively present in respective power line L1, L2, L3. The DC output of these three sets of rectifiers (RC1, RC2 and RC3) which are connected across the common cathode configured zener diodes present in power lines L1, L2, L3 are connected to filter capacitors C1, C4, C7 respectively forming a stable power supply needed for LED operation present in flasher circuits F1, F2, F3 of respective power lines L1, L2, L3. Flasher circuits F1, F2, F3 consisting of LEDs in the human viewable range is connected across each filter capacitor C1, C4, C7 of suitable value respectively.

Set of diodes (D13, D14, D15, D16), (D18, D19, D20, D21) are connected to form full bridge rectifier circuits (RC4 and RC5 respectively) and receives clipped (regulated) supply from the set of zener diodes (Z13, Z14), (Z17, Z18) respectively which are present in neutral (N) wire and ground (GND) wire respectively. The DC output of these two set of rectifiers (RC4 and RC5) which are connected across the common cathode configured zener diodes present in neutral (N) and ground wire (GND) are connected to filter capacitors C10, C16 respectively and protective zener diode Z21, Z22 respectively forming a regulated power supply needed for the operation of comparator circuit U1 and U2 respectively. Flasher circuits F4 and F5 consisting of LEDs in the human viewable range is connected across each filter capacitor C13 and C19 of suitable value present at the output of the comparator circuits U1 and U2 respectively.

The flasher circuit comprises of astable multi-vibrator circuit which flashes the two LEDs placed in it.

Impedance R13, R14 are connected in series with the voltage clipper circuits (VC4 and VC5 respectively) present in neutral (N) and ground (GND) lines.

A set of cross coupled depletion mode devices called as depletion metal-oxide-semiconductor field-effect transistor [MOSFET]—(T1, T2, T3, T4, T5, T6, T7, T8), (T9, T10, T11, T12, T13, T14, T15, T16), (T17, T18, T19, T20, T21, T22, T23, T24) and a set of current limit resistors (for example each of 11 k ohm) connected between the sources of depletion MOSFETs—(R1, R2, R3, R4), (R5, R6, R7, R8), (R9, R10, R11, R12) respectively forms the bi-directional current limiter (CL1-CL3) for power line L1, L2, L3 respectively. Drain terminal of depletion type field effect transistors T8, T16, T24 and the terminal of impedances R13, R14 which are joined together are connected to form a junction point (J1).

The operation range of the voltage presence indicating circuit (100) can be extended to any desired voltage range by modifying the rating and/or the number of cross coupled depletion mode devices i.e. depletion MOSFET along with current limiting resistor or by changing the voltage ratings of zener diodes of voltage clipper circuit. The lower value of operational voltage range i.e. the detection threshold voltage can be configured by changing the voltage ratings of zener diodes of voltage clipper circuit whereas the higher value can be configured by changing the rating and/or the number of cross coupled depletion MOSFET.

As stated above, the voltage presence indicator circuit (100) also includes two sets of unbalance sensing resistor network (SR1 and SR2) connected in star connection—first set of unbalancing sensing resistor (SR1) comprising of resistors R15, R16, R17, and the second set (SR2) comprising of resistors R21, R22, R23 with each star network of resistors set electrically connected to line wires (L1, L2, L3). The star point of unbalance sensing resistor networks (SR1 and SR2) i.e. star point J2 of R15, R16, R17 and star point J3 of R21, R22, R23 are connected to two separate signal conditioning circuits (S1, S2) respectively. The resistors of unbalance sensing resistor network (SR1 and SR2) are of high impedance for example 10 Mohm. The first signal conditioning circuit (S1) comprises of set impedance R18, a diode D17, filter capacitor C11, discharge impedance R19 and zener diode Z23. Similarly, the second signal conditioning circuit (S2) comprises of set impedance R24, a diode D22, filter capacitor C17, discharge impedance R25 and zener diode Z24. The output of each signal conditioning circuits (S1 and S2) are given as input to the comparators (U1 and U2) respectively. Comparators U1 and U2 each receives power supply, needed for its operation, from the regulated DC output of full bridge rectifiers (RC4 and RC5) connected across the zener diodes present in neutral and ground line respectively. Small bypass capacitors C12, C18 are connected across the supply pin of U1, U2 respectively. The output of comparators U1, U2 are fed to flasher circuits F4, F5 respectively via RC filter circuit containing R20, C13 and R26, C19 respectively.

Following components—four numbers of zener diodes along with eight numbers of depletion MOSFETs with their four current limiting resistors present in any power line wire (L1, L2, L3) along with four number of zener diodes in the neutral N and ground GND wire are called as main circuit components.

Further, as mentioned above, the zener diodes Z1, Z2, Z3, Z4, Z5, Z6, Z7, Z8, Z9, Z10, Z11, Z12, Z13, Z14, Z15, Z16, Z17, Z18, Z19, Z20 are divided into two groups based on their connection and usage in the circuit. First group (VC1a-VC5a) of voltage clipper circuit (VC1-VC5) includes Z1, Z2, Z5, Z6, Z9, Z10, Z15, Z16, Z19, Z20 (have rating of 15 Volts in one example embodiment) whereas second group (VC1b-VC5b) includes Z3, Z4, Z7, Z8, Z11, Z12, Z13, Z14, Z17, Z18 (have rating of 4.7 Volts in one example embodiment), wherein ratings of Zener diodes can be modified as per requirements.

In the first group of voltage clipper circuit

VC1a includes zener diodes Z1 and Z2,
VC2a includes zener diodes Z5 and Z6,
VC3a includes zener diodes Z9 and Z10,
VC4a includes zener diodes Z15 and Z16 and
VC5a includes zener diodes Z19 and Z20.

In the second group of voltage clipper circuit

VC1b includes zener diodes Z3 and Z4,
VC2b includes zener diodes Z7 and Z8,
VC3b includes zener diodes Z11 and Z12,
VC4b includes zener diodes Z13 and Z14 and
VC5b includes zener diodes Z17 and Z18.

The second group zener diodes (VC1b-VC5b) provide clipped AC input voltage to the full bridge rectifier circuit (RC1-RC5) throughout the input voltage range. The first group zener diodes (VC1a-VC5a) along with second group zener diodes (VC1b-VC5b) assist in setting the minimum/lower detection threshold voltage for indication of voltage presence in power lines L1, L2, L3. For a given current path between any two wires of the voltage presence indication circuit (100), there will be four number of zener diodes which will get forward biased and other four number will get reverse biased which will clip the voltage. For example, for the case of current path from L1 to GND with L1 at positive potential relative to GND, then the zener diodes Z2, Z4, Z19 and Z17 will get reverse biased so that total clipped voltage is summation of these zener diodes ratings which is 15+4.7+15+4.7=39.4 volts. So, if the applied voltage across L1 and GND is less than the 39.4 volts, the flasher circuit will not turn ON, which means there is no current flow in the main circuit of VPI (100) and hence the flasher LEDs (F1, F5) remains extinguished. As the applied voltage across L1 and GND is increased beyond 39.4 Volts, the current as limited by bi-directional current limiter (CL1), starts to flow through VPI circuit (100) from L1 to GND and the second group of zener diodes (VC1b) develops voltage to feed to full bridge rectifier circuit (RC1) present in the corresponding line (L1) which in turn provides filtered DC needed for operation of flasher circuit (F1). Flasher circuit (F1) will get illuminated as the DC output of the full bridge rectifier circuit (RC1) comprising of diodes D1, D2, D3, D4 is directly fed to it. It is to be noted that flasher circuit (F5) gets triggered because net voltage is developed at junction J3 which is processed by signal conditioning circuit (S2) and comparator (U2).

On the other hand, for the case of current path from GND to L1, with GND at positive potential relative to L1, then the zener diodes Z18, Z20, Z3 and Z1 will get reverse biased so that total clipped voltage is summation of these zener diodes ratings which is 15+4.7+15+4.7=39.4 volts. So, if the applied voltage across GND and L1 is less than 39.4 volts, the flasher circuit will not turn ON, which means there is no current flow in the main circuit of VPI (100) and hence the flasher circuits (F1 and F5) remains extinguished. As the applied voltage across GND and L1 is increased beyond 39.4 Volts, the current as limited by bi-directional current limiter (CL1), starts to flow through VPI circuit (100) from GND to L1 and the second group of zener diodes (VC1b) develops voltage to feed to full bridge rectifier circuit (RC1) present in the corresponding line which in turn provides filtered DC needed for operation of flasher circuit. Flasher Circuit (F1) will get illuminated as the DC output of the full bridge rectifier circuit (RC1) comprising of diodes D1, D2, D3, D4 is directly fed to it. It is to be noted that flasher circuit (F5) gets triggered because net voltage is developed at junction J3 which is processed by signal conditioning circuit (S2) and comparator (U2).

For example, for the case of current path from L1 to L2, with L1 at positive potential relative to L2, then the zener diodes Z2, Z4, Z7 and Z5 will get reverse biased so that total clipped voltage is summation of these zener diodes ratings which is 15+4.7+15+4.7=39.4 volts. So, if the applied voltage across L1 and L2 is less than 39.4 volts, the flasher circuit will not turn ON, which means there is no current flow in the main circuit of VPI (100) and hence the flasher LEDs F1, F2 remains extinguished. As the applied voltage across L1 and L2 is increased beyond 39.4 Volts, the current as limited by bi-directional current limiter (CL1 and CL2), starts to flow through VPI circuit (100) from L1 to L2 and the second group of zener diodes (VC1b and VC2b) develops voltage to feed to full bridge rectifier circuit (RC1 and RC2) present in the corresponding line which in turn provides filtered DC needed for operation of flasher circuits (F1 and F2). F1 and F2 will get illuminated as the DC output of the full bridge rectifier circuit (RC1 and RC2) comprising of set of diodes (D1, D2, D3, D4) and (D5, D6, D7, D8) respectively is directly fed to it.

On the other hand, for the case of current path from L2 to L1, with L2 at positive potential relative to L1, then the zener diodes Z6, Z8, Z3 and Z1 will get reverse biased so that total clipped voltage is summation of these zener diodes ratings which is 15+4.7+15+4.7=39.4 volts. So, if the applied voltage is applied across L2 and L1 is less than 39.4 volts, the flasher circuit will not turn ON, which means there is no current flow in the main circuit of VPI (100) and hence the flasher LEDs (F1, F2) remains extinguished. As the applied voltage across L2 and L1 is increased beyond 39.4 Volts, the current as limited by bi-directional current limiter (CL1 and CL2), starts to flow through VPI circuit (100) from L2 to L1 and the second group of zener diodes (VC1b and VC2b) develops voltage to feed to full bridge rectifier circuit (RC1 and RC2) present in the corresponding line which in turn provides filtered DC needed for operation of flasher circuits. F1 and F2 will get illuminated as the DC output of the full bridge rectifier (RC1 and RC2) circuit comprising of set of diodes (D1, D2, D3, D4) and (D5, D6, D7, D8) respectively is directly fed to it.

In one of the embodiments, the zener diodes ratings and summation of these diodes can be set as 15+4.7+15+4.7=39.4 volts (about to 40 V) which forms the lower voltage detection limit threshold in the circuit. These ratings of zener diodes and/or detection limit as described above and for example as shown in FIG. 3 are not limited. In other embodiment of the present invention, the lower voltage threshold detection value is flexibly modified as per need, such as low as 3V by changing the component ratings and thus the voltage detection value can be flexibly adjusted as per need. Examples of detection threshold voltages which are employed/set in the VPI of present invention are provided in Table—3 below.

In line L1, depletion MOSFET (T1, T2) (having intrinsic antiparallel diode) and current limit resistor (R1) forms the bi-directional current limiter circuit. The source of each depletion mode MOSFET is coupled to the gate of the opposing MOSFET, and a current limiter resistor is coupled between the sources of the MOSFETs. In this manner, current flowing in either direction through the MOSFETs and through the current limiting resistor develops a voltage across the resistor which tends to turn one MOSFET off while the other MOFSET continues to conduct through its intrinsic back body p-n junction, thereby limiting the current to a set level even with a significantly high level of voltage and regardless of the direction of the current provided at the input. For this operation, the intrinsic body of one mosfet (which is in conduction) along with the intrinsic diode of 2^{nd} MOSFET will be used. Three more sets of such bi-directional current limiter are connected in series with the first bi-directional current limiter (comprising of T1, R1, T2) forming the bi-directional current limiter circuit (CL1). Voltage blocking capacity of each MOSFET used in the present invention is 600 volts, hence the series connection of such cross connected module will help in enhancing the voltage handling capacity of the voltage presence indicator circuit (100). The present indicating circuit can function for voltage range up to 1732 (line to neutral value) or 3000 volts (line to line value). It is to be noted that the higher voltage operation range of the voltage presence indicating circuit (100) can be extended to any desired range by modifying the rating or/and the number of cross coupled depletion mode devices along with resistor in series with the existing cross coupled depletion mode devices, The circuit of L1, L2 and L3 power line wire are similar to each other.

Considering the case of ground wire, the zener diodes Z17 and Z18 provide clipped AC voltage to the full bridge rectifier circuit (RC5) comprising of D18, D19, D20, D21 and capacitor C16. This circuit helps in converting the clipped AC input voltage into filtered DC voltage. Protective zener diode (Z22) forms a stable power supply needed for comparator (U2) operation. The circuit of neutral N wire is similar to ground GND wire as described above.

Unbalance sensing resistor network (SR2) comprises of 3 resistors (R21, R22, R23) of high impedance connected in star connection to form a star junction point (J3). The resistors R21, R22 and R23 are of equal value. During normal power operation when the voltages in line L1, L2 and L3 are in balanced condition, the summation of net voltage formed at the star junction point is zero. However, during the unbalanced condition, there exist some net voltage at the star junction point (J3). This voltage is processed through signal conditioning circuit (S2). Diode D22 along with capacitor C17 helps in converting the AC voltage at the star junction point (J3) into filtered DC signal which is fed as an input to positive input pin of comparator (U2). Comparator (U2) compares this input voltage value with a fixed value which is internally generated temperature compensated value and triggers the flasher circuit (F5). The discharge resistor R25 having high impedance is connected across the capacitor. High value of R25 does not allow the rapid discharging of capacitor voltage and the voltage remains available for comparator (U2) for the purpose of unbalance condition indication using flasher circuit (F5). When the balanced condition restores, the vector sum voltage available at the junction point (J3) becomes zero during which the capacitor C17 starts discharging through discharge resistor R25 because of which the voltage at the positive input pin of the comparator (U2) goes below the set reference value present at the second input pin of U2, thus making the flasher circuit F5 extinguished.

Flasher F4 also works on the same principle in conjunction with high impedances R15, R16, R17, signal conditioning circuit, S1 and comparator, U1.

Consider an application in which L1 and GND wire of the voltage presence indicator circuit (100) are connected to L1 and GND of the power line respectively for the application of single phase AC supply or to the positive and negative supply wires of two wire DC supply. Also, the condition that the breaker is switched OFF to disconnect the circuit for maintenance purpose.

If an electrical potential exist between L1 and GND with L1 being positive relative to GND, then the zener diodes Z2, Z4, Z19 and Z17 will get reverse biased and current in the main circuit components as set by the cross coupled bi-directional current limiter circuit (CL1) will flow via path Z1-Z2-Z3-Z4-T1-R1-T2-T3-R2-T4-T5-R3-T6-T7-R4-T8-R14-Z20-Z19-Z18-Z17.

It is to be noted that a part of this current will flow through branch circuit comprising of full bridge rectifier circuit (RC1) formed of D1, D2, D3, D4 and C1 and also through full bridge rectifier circuit (RC5) formed of D18, D19, D20, D21 and C16 needed for operation of flasher circuit F1 and F5 respectively. Developed voltage across the zener diodes Z3, Z4 is used to drive flasher circuit (F1), via a full bridge rectifier circuit (RC1) comprising of diodes D1, D2, D3 and D4. Developed voltage across the zener diodes Z17, Z18 is used to provide regulated DC supply to comparator (U2) via a full bridge rectifier circuit (RC5) comprising of diodes D18, D19, D20 and D21. The summation of net voltage at junction J3 is not zero and above the set value (as tuned by impedance R24). This voltage is conditioned by signal conditioning circuit (S2) and fed to the positive input pin of comparator (U2). Comparator (U2) compares this input voltage value with a fixed value which is internally generated temperature compensated value and triggers the flasher circuit (F5). Thus, both the flasher circuit F1 and F5 will get illuminated indicating the presence of voltage in both the lines L1 and GND.

On the other hand, if an electrical potential exist between GND and L1 with GND being positive relative to L1, then the zener diodes Z18, Z20, Z3 and Z1 will get reverse biased and current in the main circuit components as set by the cross coupled bi-directional current limiter circuit (CL1) will flow via path Z17-Z18-Z19-Z20-R14-T8-R4-T7-T6-R3-T5-T4-R2-T3-T2-R1-T1-Z4-Z3-Z2-Z1. It is to be noted that a part of this current will flow through branch circuit comprising of full bridge rectifier circuit (RC1) formed of D1, D2, D3, D4 and C1 and also through full bridge rectifier circuit (RC5) formed of D18, D19, D20, D21 and C16 needed for operation of flasher circuit F1 and F5 respectively. Developed voltage across the zener diodes Z3, Z4 is used to drive flasher circuit (F1), via a full bridge rectifier circuit (RC1) comprising of diodes D1, D2, D3 and D4. Developed voltage across the zener diodes Z17, Z18 is used to provide regulated DC supply to comparator (U2) via a full bridge rectifier circuit (RC5) comprising of diodes D18, D19, D20 and D21. The summation of net voltage at junction J3 is not zero and above the set value (as tuned by impedance R24). This voltage is conditioned by signal conditioning circuit (S2) and fed to the positive input pin of comparator (U2). Comparator (U2) compares this input voltage value with a fixed value which is internally generated temperature compensated value and triggers the flasher circuit (F5). Thus, both the flasher circuits F1 and F5 will get illuminated indicating the presence of voltage in both the lines L1 and GND.

The flow of current in L2 and GND, L3 and GND, L1 and N, L2 and N, and L3 and N are identical in operation to L1 and GND as mentioned above.

Consider an application in which L1 and L2 wire of the voltage presence indicator circuit (100) are connected to L1 and GND of the power line respectively for the application of single phase AC supply or to the positive and negative supply wires of two wire DC supply. Also the condition that the breaker is switched OFF to disconnect the circuit for maintenance purpose.

If an electrical potential exist between L1 and L2 with L2 being positive relative to L1, then the zener diodes Z6, Z8, Z3 and Z1 will get reverse biased and current in the main circuit components as set by the cross coupled bi-directional current limiter circuits (CL1 and CL2) will flow via path Z5-Z6-Z7-Z8-T9-R5-T10-T11-R6-T12-T13-R7-T14-T15-R8-T16-T8-R4-T7-T6-R3-T5-T4-R2-T3-T2-R1-T1-Z4-Z3-Z2-Z1. It is to be noted that a part of this current will flow through branch circuit comprising of full bridge rectifier circuit (RC1) formed of D1, D2, D3, D4 and C1 and also through full bridge rectifier circuit (RC2) formed of D5, D6, D7, D8 and C4 needed for operation of flasher circuit F1 and F2 respectively. Developed voltage across the zener diodes Z3, Z4 is used to drive flasher circuit (F1) via a full bridge rectifier circuit (RC1) comprising of diodes D1, D2, D3 and D4. Similarly, developed voltage across the zener diodes Z8, Z7 is used to drive flasher circuit (F2) via a full bridge rectifier circuit (RC2) comprising of diodes D5, D6, D7 and D8. Thus, both the flasher circuit F1 and F2 will get illuminated indicating the presence of voltage in both the power lines L1 and L2.

On the other hand, if an electrical potential exist between L2 and L1 with L1 being positive relative to L2, then the zener diodes Z2, Z4, Z7 and Z5 will get reverse biased and current in the main circuit components as set by the cross coupled bi-directional current limiter circuit (CL1 and CL2) will flow via path Z1-Z2-Z3-Z4-T1-R1-T2-T3-R2-T4-T5-R3-T6-T7-R4-T8-T16-R8-T15-T14-R7-T13-T12-R6-T11-T10-R5-T9-Z8-Z7-Z6-Z5. It is to be noted that a part of this current will flow through branch circuit comprising of full bridge rectifier circuit (RC1) formed of D1, D2, D3, D4 and C1 and also through full bridge rectifier circuit (RC2) formed of D5, D6, D7, D8 and C4 needed for operation of flasher circuit F1 and F2 respectively.

Developed voltage across the zener diodes Z3, Z4 is used to drive flasher circuit (F1) via a full bridge rectifier circuit (RC1) comprising of diodes D1, D2, D3 and D4. Similarly, developed voltage across the zener diodes Z8, Z7 is used to drive flasher circuit (F2) via a full bridge rectifier circuit (RC2) comprising of diodes D5, D6, D7 and D8. Thus, both the flasher circuit F1 and F2 will get illuminated indicating the presence of voltage in both the power lines L1 and L2.

The flow of current in L3 and L2, L1 and L3, are identical in operation to L1 and L2 as mentioned above.

Consider the three phase application of the voltage presence indicating circuit in which L1, L2, L3 wires of the circuit are connected to the phase/power lines and GND and N wires of the circuit are connected to the ground and neutral of the supply system.

During normal operation when the power lines L1, L2 and L3 are energized and the breaker is in ON condition and the voltages in these lines are in balanced condition and greater in magnitude than the set detection threshold voltage, the LEDs of flasher circuit (F1, F2, F3) for their respective power lines will get illuminated as they are getting DC supply from their respective connected full bridge rectifier circuits (RC1, RC2 and RC3). The LEDs of flasher circuit (F4, F5) during this condition will be extinguished as the summation of net voltage formed at the junction point of unbalance sensing resistor network (J2, J3) is zero because of balanced supply. This operation of flasher circuits—F1, F2, F3, F4, F5 is peculiar to balanced condition operation in which F1, F2, F3 gets illuminated and F4, F5 remains extinguished. This condition occurs when Delta or Wye-3 phase systems are in balanced state.

Besides non-illumination due to absence of net voltage at junction J2 and J3, the F4 and F5 will also not get illuminated (remain extinguished) from a fully isolated ground system even during unbalance condition since the ground current path is open. Only a leakage failure to ground would create a path for current to flow through GND wire.

For the condition, where the voltage in all the power lines are more than the minimum detection threshold voltage and are not equal in magnitude and the summation of net voltage formed at the junction point J2 and J3 is above a set value (which can be tuned by impedance R18 and R24 for J2 and J3 respectively), the flasher circuit F4 and F5 get illuminated along with flasher circuit F1, F2 and F3. Thus, the circuit gives indication for the balanced supply condition and unbalanced supply condition. During unbalance condition, flasher circuit F1, F2 and F3 may retain higher intensity than the flasher circuit F4 and F5. It should be noted that although the voltage presence indicator circuit (100) gives indication for unbalance and leakage condition, this circuit is not specifically designed as a detector for these conditions.

As mentioned above, the VPI circuit provides indication via LEDs present in flasher circuit F4 and F5, for unbalance voltage condition for three phase power supply system for the duration the unbalance condition is present in the supply system. Once the balanced condition restores from unbalanced condition, the high impedance discharge resistors (R19 and R25) placed across the capacitor (C11 and C17) present in signal conditioning circuit (S1 and S2) discharges the corresponding capacitor thereby reducing the voltage available at the positive input pin of comparator (U1 and U2) as compared to the negative input pin of the comparator and thus making the LEDs of flasher circuit (F4 and F5) extinguished.

The various current path of the main circuit components are summarized in Table 1.

TABLE 1
Current Path in main circuit components

| Positive | Negative | |
|---|---|---|
| line | line | Current path |
| L1 | L2 | Z1-Z2-Z3-Z4-T1-R1-T2-T3-R2-T4-T5-R3-T6-T7- |
| | | R4-T8-T16-R8-T15-T14-R7-T13-T12-R6-T11-T10- |
| | | R5-T9-Z8-Z7-Z6-Z5 |
| L1 | L3 | Z1-Z2-Z3-Z4-T1-R1-T2-T3-R2-T4-T5-R3-T6-T7- |
| | | R4-T8-T24-R12-T23-T22-R11-T21-T20-R10-T19- |
| | | T18-R9-T17-Z12-Z11-Z10-Z9 |
| L1 | N | Z1-Z2-Z3-Z4-T1-R1-T2-T3-R2-T4-T5-R3-T6-T7- |
| | | R4-T8-R13-Z16-Z15-Z14-Z13 |
| L1 | GND | Z1-Z2-Z3-Z4-T1-R1-T2-T3-R2-T4-T5-R3-T6-T7- |
| | | R4-T8-R14-Z20-Z19-Z18-Z17 |
| L2 | L1 | Z5-Z6-Z7-Z8-T9-R5-T10-T11-R6-T12-T13-R7- |
| | | T14-T15-R8-T16-T8-R4-T7-T6-R3-T5-T4-R2-T3- |
| | | T2-R1-T1-Z4-Z3-Z2-Z1 |
| L2 | L3 | Z5-Z6-Z7-Z8-T9-R5-T10-T11-R6-T12-T13-R7- |
| | | T14-T15-R8-T16-T24-R12-T23-T22-R11-T21-T20- |
| | | R10-T19-T18-R9-T17-Z12-Z11-Z10-Z9 |
| L2 | N | Z5-Z6-Z7-Z8-T9-R5-T10-T11-R6-T12-T13-R7- |
| | | T14-T15-R8-T16-R13-Z16-Z15-Z14-Z13 |
| L2 | GND | Z5-Z6-Z7-Z8-T9-R5-T10-T11-R6-T12-T13-R7- |
| | | T14-T15-R8-T16-R14-Z20-Z19-Z18-Z17 |
| L3 | L1 | Z9-Z10-Z11-Z12-T17-R9-T18-T19-R10-T20-T21- |
| | | R11-T22-T23-R12-T24-T8-R4-T7-T6-R3-T5-T4- |
| | | R2-T3-T2-R1-T1-Z4-Z3-Z2-Z1 |
| L3 | L2 | Z9-Z10-Z11-Z12-T17-R9-T18-T19-R10-T20-T21- |
| | | R11-T22-T23-R12-T24-T16-R8-T15-T14-R7-T13- |
| | | T12-R6-T11-T10-R5-T9-Z8-Z7-Z6-Z5 |
| L3 | N | Z9-Z10-Z11-Z12-T17-R9-T18-T19-R10-T20-T21- |
| | | R11-T22-T23-R12-T24- R13-Z16-Z15-Z14-Z13 |
| L3 | GND | Z9-Z10-Z11-Z12-T17-R9-T18-T19-R10-T20-T21- |
| | | R11-T22-T23-R12-T24- R14-Z20-Z19-Z18-Z17 |

The circuit provides desired operation for any three phase sequence. The L1, L2 and L3 wire of the VPI circuit (100) can be connected to any phase/power line. The N and GND wire of the VPI circuit can be interchanged between the two and cannot be connected to the main lines of the circuit of electrical power system (L1, L2, and L3). Even with the incorrect connection of the wires among its group, the circuit will detect the presence of hazardous potential, however incorrect connection may lead to confusion in identifying the line carrying the electrical energy potential.

The circuit is configured to provide indication of hazardous potential in the lines using LEDs present in flasher circuit. However, remote monitoring capability can also be added to the circuit. For example, opto-coupler circuit including an opto-coupler input can be electrically arranged in series with LEDs which are part of flasher circuit to produce optically isolated signals for isolated remote monitoring.

The L1, L2 and L3 indicators can be converted to solid ON indication by placing the LEDs in series with the cross coupled depletion mode devices along with resistor in series and by eliminating the diode rectifier (RC1, RC2, RC3) and flasher circuit (F1, F2, F3). For indicating the unbalanced condition of the circuit in solid ON version, the LEDs are to be replaced in the place of C13 and C19 capacitors and eliminating the flasher circuits F4 and F5.

Thus, the above explanation can be summarized as, the present invention provides a voltage presence indicator (100) for monitoring of hazardous electrical potential of a plurality of electrical power input lines of an AC/DC circuit, the voltage presence indicator (100) comprises:
plurality of voltage clipper circuits (VC1-VC5) comprising of first group of voltage clipper circuits (VC1a-VC5a) and second group of voltage clipper circuits (VC1b-VC5b);
plurality of bi-directional current limiter circuits (CL1-CL3);
plurality of full-bridge rectifier circuits (RC1-RC5);
plurality of unbalance sensing resistor circuits (SR1-SR2);
plurality of signal conditioning circuits (S1-S2);
plurality of comparator circuits (U1-U2); and
plurality of flasher circuits (F1-F5),
wherein the plurality of the voltage clipper circuits (VC1-VC5) are divided into two groups i.e. first group (VC1a-VC5a) and second group (VC1b-VC5b), the first group (VC1a-VC5a) and second group (VC1b-VC5b) of zener diodes together sets the low voltage detection thresholds of VPI circuit for visual indication for presence of hazardous electrical energy potential in the circuit and the second group (VC1b-VC5b) of zener diodes is used to provide ac clipped voltage to the said full bridge rectifier circuits (RC1 to RC5) present in all the lines L1, L2, L3, N, GND; which is needed for flasher circuit (F1-F5) operation,
wherein the plurality of bi-directional current limiter circuits (CL1-CL3) comprises of cross coupled depletion mode MOSFET (T1-T24) where the source of each depletion mode MOSFET (T1-T24) is coupled to the gate of the opposing MOSFET (T1-T24), and a current limiter resistor is coupled between the sources of the MOSFETs, wherein the cross coupled depletion MOSFET along with current limiting resistor connected electrically in series with the zener diode group of power line wire L1, L2, L3 limits the current to a set level even with the application of significant high voltage and regardless of the voltage polarity available at the terminals (L1, L2, L3, N and GND);
wherein the diode based full bridge rectifier circuits (RC1-RC3) receives clipped voltage from the second group (VC1b-VC3b) of zener diodes present in power lines L1, L2, L3 for providing DC output to the flasher circuit (F1-F3) and the diode based full bridge rectifier circuits (RC4-RC5) receives clipped voltage from the second group (VC4b-VC5b) of zener diodes present in neutral N and ground GND wire for providing DC voltage to the supply pins of comparator circuits (U1-U2) for unbalance condition detection,
wherein the unbalance sensing resistor networks (SR1 and SR2) connected in star connection where each resistor (R15, R16, R17, R21, R22 and R23) is of high impedance and equal in value connected electrically to power line wires, wherein the function of this resistor network (SR1 and SR2) is to sense the voltage unbalance condition in the power line and provide vector sum voltage at the junction point to be processed for providing indication of unbalance condition, with the help of flasher circuit (F4 and F5);
wherein the signal conditioning circuits (S1 and S2) comprising of set resistor (R18, R24), rectifier diode (D17, D22), capacitor (C11, C17) along with discharge resistor (R19, R25) and zener diode (Z23, Z24), wherein the set resistor fixes the percentage unbalance voltage value at which the flasher circuit (F4, F5) gives indication for unbalance condition, rectifier diode (D17, D22) provides DC voltage needed to charge the capacitor (C11, C17), high impedance discharge resistor (R19, R25) discharges the parallel connected capacitor (C11, C17) thereby reducing the voltage available at the positive input pin of comparator (U1, U2) during the condition of restoring the balanced voltage condition from unbalanced condition, and thus making the corresponding flasher (F4 and F5) extinguished; and wherein the comparator circuits (U1 and U2) which compares the output of signal conditioning circuit with its internally generated temperature compensated value for detection of unbalance condition.

Further, in the voltage presence indicator (100), plurality of high impedance bi-directional current limiters are connected in series with set of common cathode configuration zener diodes; wherein the plurality of cross coupled depletion MOSFETs (T1-T24) along with associated current limiting resistors of bi-directional current limiter offers variable impedance based on the applied input voltage; wherein clipped ac voltage across the common cathode configured second group of zener diode is rectified through full bridge rectifier—at the output of which flasher circuit is connected. Thus the series arrangement of common cathode configured first and second group zener diodes and cross coupled depletion MOSFETs along with associated current limiting resistors ensures operation of flasher circuit which drives LEDs for the whole input voltage range. The voltage presence indicator (100) is provided with the plurality of rectifying paths in which a part of main circuit component current flows through the branch circuit comprising of full bridge rectifier circuits (RC1-RC5) and filter capacitors associated with full bridge rectifier circuits (RC1-RC5). The plurality of sensing resistor network (SR1-SR2) comprising equal value and high impedances connected in star fashion wherein each set of resistor (R15, R16, R17 and R21, R22, R23) of the sensing resistor network (SR1 and SR2) is communicating with the phase lines to sense the unbalance voltage condition. The plurality of signal conditioning circuits (S1-S2) which processes the voltage at the junction points (J2 and J3) of sensing resistor network (SR1-SR2) to provide signal voltage to the comparator (U1-U2) to trigger flasher circuit (F4, F5) of neutral or ground wire. The plurality of high impedance discharge resistor (R19 and R25) placed across the capacitor (C11 and C17) present in signal conditioning circuit which discharges the parallel connected capacitor (C11 and C17) and helps in reducing the voltage available at the positive input pin of comparator during the condition of restoring the balanced voltage condition from unbalanced condition, thus making the corresponding flasher extinguished and the set resistor (R18 and R24) are connected at the junction point of sensing resistor network to tune the percentage unbalance voltage value at which the flasher circuit starts giving indication for unbalance condition.

In another aspect of the present invention, the present invention provides a method for providing warning of a hazardous electrical voltage on a circuit using the voltage presence indicator (100), wherein the method includes arranging plurality of high impedance bi-directional current limiters along with associated current limiting resistors are connected in series with set of common cathode configuration zener diodes in which cross coupled depletion MOSFETs along with associated current limiting resistors of bi-directional current limiter offers variable impedance based on the applied input voltage and the clipped ac voltage across the common cathode configured second group zener diode is rectified through full bridge rectifier—at the output of which flasher circuit is connected. Thus the method of series arrangement common cathode configured first and second group zener diodes and cross coupled depletion MOSFETs along with associated current limiting resistors ensures the operation of flasher circuit which drives LEDs for the whole input voltage range. Further, the method includes limiting the current flowing in a high impedance path irrespective of the magnitude of hazardous electrical voltage.

Yet in another aspect of the present invention, the present invention provides a method for providing detection for unbalance condition in three phase circuit, the method includes arranging a set of resistor network (SR1-SR2) connected in star connection along with signal conditioning circuits (S1-S2), comparator circuits (U1-U2) wherein comparator circuits (U1-U2) receives DC voltage for its operation from the full bridge rectifier circuits (RC4-RC5) connected to the second group (VC4b-VC5b) of zener diodes present in neutral or ground wire. The said method further includes the set of second group (VC4b-VC5b) of zener diodes which provides clipped ac voltage to the full bridge rectifier (RC4-RC5) present in the neutral and ground wire are connected electrically to the neutral and ground terminal of the circuit.

As mentioned above, the said Voltage Presence Indicator monitors a wide range of stored electrical potentials based upon the rating of the components. However, as an embodiment of the present invention and for understanding the electrical circuitry flow, particular rating/value of the components are used in the present invention as shown in FIG. 3. A person skilled in art will understand that the invention is not limited to the particular said value and can be employed using different set of rating based upon the voltage rating for which the Voltage presence indication (100) is being used. For example, the bidirectional current limiter which are placed in L1, L2 and L3 can also be placed suitably in N and GND wire to make the main circuit symmetrical in terms of placement of components in line wires (L1, L2, L3) and neutral wire (N) and ground wire (GND).

Further, Table 2 shows the obtained higher detection voltage values for various numbers of cross coupled MOSFET modules present in each line (L1, L2, L3) wherein a cross coupled mosfet module consists of 2 numbers of depletion mosfets connected electrically to each other and a current limiting resistor in such a way that the source of each depletion mode MOSFET is coupled to the gate of the opposing MOSFET, and a current limiter resistor is coupled between the sources of the MOSFETs. It is to be noted that the various voltage values mentioned in the table 2 are based on theoretical calculations and sufficient safety margin need to be introduced during usage.

TABLE 2
Calculated higher detection voltage values for
various numbers of cross coupled mosfet modules

| | Drain to source | | | Single | |
|---|---|---|---|---|---|
| | breakdown | Maximum | Maximum | phase rms | Three phase |
| No. of | voltage of a | DC voltage | DC voltage | voltage | rms voltage |
| cross | cross coupled | handling | handling | handling | handling |
| coupled | mosfet module | value (Line | value (Line | value (Line | value (Line |
| mosfet | (maximum | to Ground | to Line | to Ground | to Line |
| module | value) | wires) | wires) | wires) | value) |
| 1 | 600 volts | 600 volts | 1200 volts | 424 volts | 735 volts |
| 2 | 600 volts | 1200 volts | 2400 volts | 849 volts | 1470 volts |
| 3 | 600 volts | 1800 volts | 3600 volts | 1273 volts | 2205 volts |
| 4 | 600 volts | 2400 volts | 4800 volts | 1697 volts | 2940 volts |
| 5 | 600 volts | 3000 volts | 6000 volts | 2122 volts | 3675 volts |

Table 3 shows the selection of zener diodes (present in voltage clipper circuit) values for setting various detection threshold voltage values.

TABLE 3
selection of zener diodes values for
detection threshold voltage values

| | | |
|---|---|---|
| First group Zener | Second group Zener | Detection Threshold |
| diode voltage value | diode value | voltage |

| | | | | |
|---|---|---|---|---|
| 0 | volts | 1.5 volts | 3 | volts |
| 1.5 | volts | 4.7 volts | 12.4 | volts |
| 5.1 | volts | 4.7 volts | 19.6 | volts |
| 15 | volts | 4.7 volts | 39.4 | volts |

Further, the power consumption of the VPI circuit can be optimized by modifying the values of following resistors present in the circuit:

1. Current limiting resistors (R1-R12) connected between the source terminals of cross coupled depletion MOSFETs. Keeping too high value of these resistors in order to minimize the power consumption of the circuit may lead to very dim flashing of LEDs of flasher circuit (F1-F3) which may interfere with identification of presence of hazardous voltage present in the power lines.

2. Resistors present in unbalance sensing resistor network SR1 (R15-R17) and SR2 (R21-R23). Too high value of these resistors may lead to false detection of unbalance voltage as the sensing resistor network circuit becomes prone to interference of external noise from panel.

Further, the power consumption of the developed voltage presence indicator circuit is provided in Table—4 below.

TABLE 4
Power consumption of the developed VPI circuit

| | | | | | Calculated |
|---|---|---|---|---|---|
| | | | Calculated | | Total Power |
| | | | power | | consumption |
| | | Measured | consumption | | in 3 phase |
| Supply | Supply Voltage | current | in a phase | | system |
| system | (V) | in a phase | (in Watts) | | (in Watts) |
| 3 phase ac | Phase to Neutral | 0.313 mA | 0.136 | W | 0.41 W |
| voltage | value: 433 V | | | | |
| | Line to line | | | | |
| | value: 750 V | | | | |
| | Phase to Neutral | 0.508 mA | 10.44 | W | 1.32 W |
| | value: 866 V | | | | |
| | Line to line | | | | |
| | value: 1500 V | | | | |
| DC power | DC voltage: | 0.580 mA | 0.58 | W | — |
| supply with | 1000 V | | | | |
| voltages | DC voltage: | 0.811 mA | 1.22 | W | — |

| | |
|---|---|
| applied | 1500 V |
| between L1 | |
| and N wire | |
| of the devel- | |
| oped circuit | |

Further, referring to FIG. 4 to FIG. 8 of the present invention, the present invention provides various embodiments of the circuit of electrical power system connected in different configurations.

With reference to FIG. 4, it shows the second embodiment of the present invention where the circuit (200′) of electrical power system consists of three phase delta connected load (50′) that is driven through lines L1′, L2′, L3′ by three phase power with respect to ground potential GND′. The circuit includes plurality of electrical power lines comprising a three phase lines (L1′, L2′ and L3′) and a ground (GND′) line, the current in the main circuit components flows from three phase lines (L1′, L2′ and L3′) to ground (GND′) wire via a common junction of line wires. The circuit further comprises of the circuit breaker (CB) and a voltage presence indicating circuit (100′). The power is presently disconnected via a circuit breaker (CB) such that the lines are electrically isolated and at zero potential. The voltage presence indicating circuit (100′) which is substantially similar to the voltage presence indicating circuit (100) of embodiment 1 and suitably includes the circuitry (100′), monitors the power system circuit (200′) for hazardous electrical energy potentials. As the circuit (200′) includes only L1′, L2′, L3′ and GND′, the neutral wire, N of the VPI circuit (100′) is preferably connected to the ground potential, GND′. Working of the VPI circuit (100′) is similar to that of the VPI circuit (100) as explained for FIG. 1.

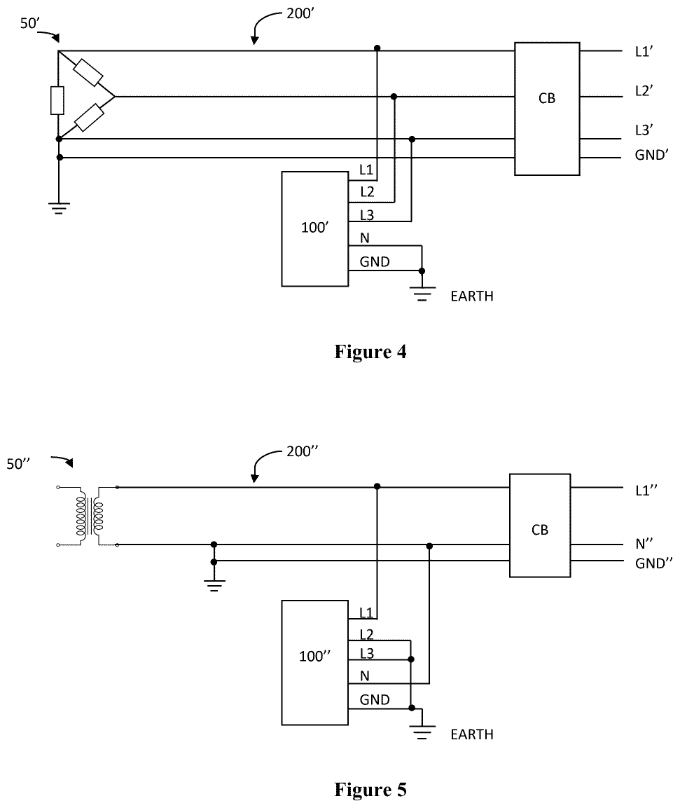

With reference to FIG. 5, it shows the third embodiment of the present invention where the circuit (200″) of electrical power system consists of single phase two wire load (50″) that is driven through power line L1″ and neutral N″ by single phase power relative to ground potential GND″. The circuit (200″) includes a plurality of electrical power lines comprising a single phase line (L″), a neutral line (N″) and a ground (GND″) line, the current in the main circuit components flows between three phase lines (L1, L2 and L3) in normal balanced condition and the current flows through ground (GND) and neutral (N) wire in unbalanced condition. The circuit further comprises of the circuit breaker (CB) and a voltage presence indicating circuit (100″). The power is presently disconnected via a circuit breaker (CB) such that the lines are electrically isolated and at zero potential. The voltage presence indicating circuit (100″) which is substantially similar to the voltage presence indicating circuit (100) of embodiment and suitably includes the circuitry (100″), monitors the power system circuit (200″) for hazardous electrical energy potentials. As the circuit (200″) includes only L1″, N″ and GND″, the L2 and L3 wires of the VPI circuit (100″) are preferably connected to the ground potential GND″. Working of the VPI circuit (100″) is similar to that of the VPI circuit (100) as explained for FIG. 1.

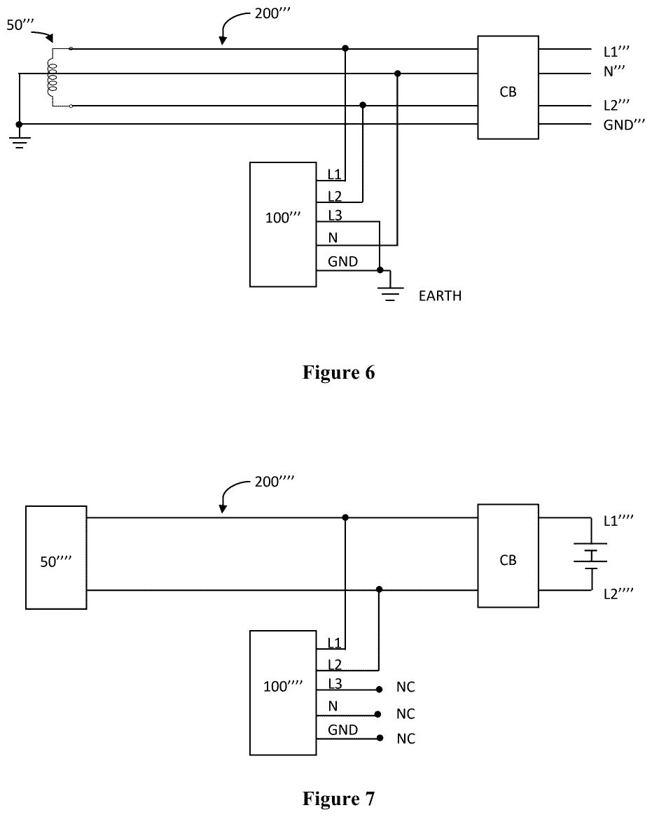

With reference to FIG. 6, it shows the fourth embodiment of the present invention where the circuit (200′″) of electrical power system consists of single phase three wire load (50′″) that is driven through differential power lines L1′″, L2′″ and neutral N′″ by single phase power relative to ground potential GND′″. The circuit includes plurality of electrical power lines comprising two differential ac lines (L1′″ and L2′″), a neutral line (N″) and a ground (GND′″) line, the current in the main circuit components flows from two differential ac lines (L1′″ and L2′″) to ground (GND′″) and neutral (N′″) wire via a common junction of line wires. The circuit further comprises of the circuit breaker (CB) and a voltage presence indicating circuit (100′″). The power is presently disconnected via a circuit breaker (CB) such that the lines are electrically isolated and at zero potential. The voltage presence indicating circuit (100′″) which is substantially similar to the voltage presence indicating circuit (100) and suitably includes the circuitry (100), monitors the power system circuit (200′″) for hazardous electrical energy potentials. As the circuit (200′″) includes only L1′″, L2′″, N′″ and GND′″, the L3 wire of the VPI circuit (100′″) is preferably connected to the ground potential GND′″. Working of the VPI circuit (100′″) is similar to that of the VPI circuit (100) as explained for FIG. 1.

With reference to FIG. 7, it shows the fifth embodiment of the present invention where the circuit (200″″) of electrical power system consists of 2 wire DC load (50″″) that is driven through L1″″ and L2″″ in which L2″″ is having negative potential with respect to L1″″. The circuit includes plurality of electrical power lines include two wire (L1″″, L2″″) DC system, the current in the main circuit components flows from positive power line (L1″″) to negative power line (L2″″) via a common junction of line wires. The circuit further comprises of the circuit breaker (CB) and a voltage presence indicating circuit (100″″). The power is presently disconnected via a circuit breaker (CB) such that the lines are electrically isolated and at zero potential. The voltage presence indicating circuit (100″″) which is substantially similar to the voltage presence indicating circuit (100) and suitably includes the circuitry (100), monitors the power system circuit (200″″) for hazardous electrical energy potentials. As the circuit (200″″) includes only L1″″ and L2″″, the L3, N and GND wire of the VPI circuit are kept as not connected. Working of the VPI circuit (100″″) is similar to that of the VPI circuit (100) as explained for FIG. 1. It is to be noted that in this non safety DC application, any of the 2 wires of VPI circuit comprising of minimum one line wire of the VPI circuit, can be used for the purpose of indication of presence of hazardous potential

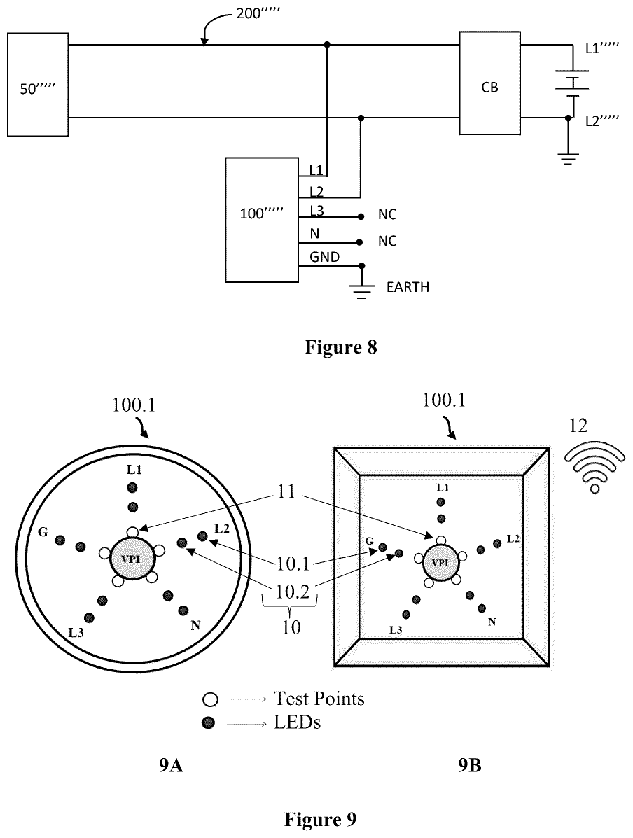

With reference to FIG. 8, it shows the sixth embodiment of the present invention where the circuit (200′″″) of electrical power system consists of 2 wire DC load (50′″″) that is driven through L1′″″ and L2′″″ in which L2′″″ is having negative potential with respect to L1′″″ and L2′″″ is at ground potential GND. The circuit includes plurality of electrical power lines comprises two wire (L1′″″ and L2′″″) DC system and a ground line (GND), the current in the main circuit components flows from positive (L1′″″) and negative (L2′″″) power line to ground (GND) via a common junction of line wires. The circuit further comprises of the circuit breaker (CB) and a voltage presence indicating circuit (100′″″). The power is presently disconnected via a circuit breaker (CB) such that the lines are electrically isolated and at zero potential. The voltage presence indicating circuit (100′″″) which is substantially similar to the voltage presence indicating circuit (100) and suitably includes the circuitry (100), monitors the power system circuit (200′″″) for hazardous electrical energy potentials. As the circuit (200′″″) includes only L1′″″, L2′″″ and GND, the L3 and N wire of the VPI circuit are kept as not connected. Working of the VPI circuit (100′″″) is similar to that of the VPI circuit (100) as explained for FIG. 1. It is to be noted that in this safety DC application, any of the 2 wires comprising of minimum one line wire of the VPI circuit, can be used for the purpose of indication of presence of hazardous potential.

Referring FIG. 9, exemplary models of visual display module (100.1) with LEDs for indication of the VPI system/device are shown, wherein any suitable shape of visual model can be used in the VPI of present invention. In one example embodiment, FIG. 9A shows a Circular display model of visual module. In one example embodiment, FIG. 9B shows Polygonal display model of visual module. The visual display module (100.1) with LEDs for indications can be suitably placed at the electrical panel. As shown in figures the display comprises plurality of LEDs (10) such as two LEDs (10.1, 10.2) which flash upon when a dangerous voltage is present in the circuit. Test points (11) can be provided in the VPI circuit for verifying the voltage measurement at the door (14) using portable test instrument. In one embodiment, the visual display module (100.1) comprises a wireless communication system such as Wi-Fi (12) as shown in FIG. 9B, which enables the display device (100.1) to be monitored and/or display indications are read remotely, via other suitable portable devices such as mobile, which is connected with the display (100.1) via network connection.

Yet in another embodiment of the present invention, the said voltage presence indicator circuitry (100, 100′,100″, 100′″, 100″″, 100′″″) is presented in various surface mount arrangement.

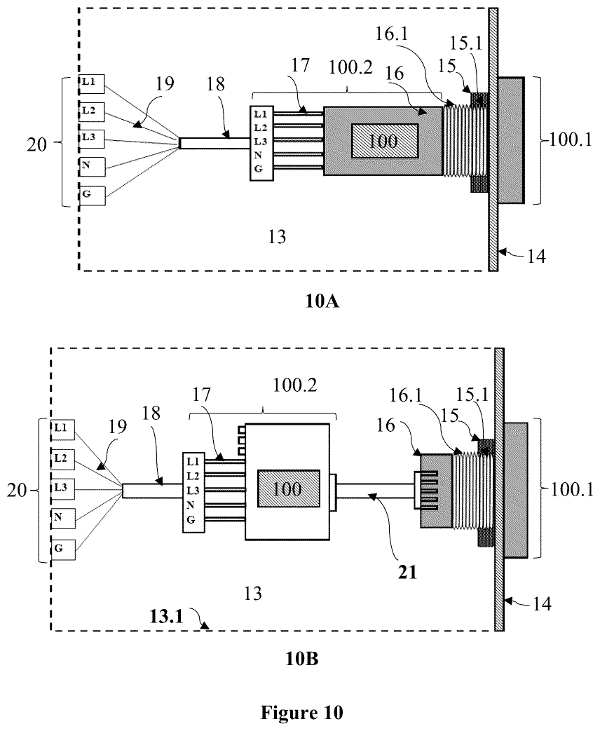

Thus, in one embodiment, the VPI system/device of present invention (100) comprises visual display module (100.1) and VPI circuit module (100.2), wherein these two modules (100.1, 100.2) can be provided in rigid permanent connected form (FIG. 10A) or can also be provided separately which may be connected via a suitable cable connection to form the complete VPI (FIG. 10B).

FIG. 10 shows mounting assembly and/or system of VPI system/device in an electrical panel, wherein it comprises VPI system/device (100) comprising visual display module (100.1) and VPI circuit module (100.2) mounted on a door (14) of an electrical panel box (13). The VPI may be mounted on the door (14) via a hole (14.1) of the door (14) of the panel box (13).

Referring FIG. 10A, it shows a mounting system where complete VPI system/device is mounted on the opening door (14) of an electrical panel box (13), wherein visual display module (100.1) and VPI circuit module (100.2) are placed in direct attachment with the help of thread (16.1) of the inner body (16) of VPI that engages with thread (15.1) of a fixing member (15), such that member (15) upon engagement, hold/attach the VPI (100) with the door (14) of the panel box (13). The back side of the VPI which remains present inside the panel box (13) comprises line wires connections (L1, L2, L3, N, and GND) (referred as 17) which may be optionally then forwarded in a single cable/conduit (18) connecting the leads (19) of the five wires to source voltage such as at source points (20).

Yet in another embodiment of the present invention, the said voltage presence indicator circuitry (100, 100′, 100″, 100′″, 100″″, 100′″″) is presented in an alternative surface mount arrangement. The circuitry is placed in isolation module that can be kept inside the panel and only the light indication is brought to the door of panel by using a fiber optic cable or other indicating methods as shown in FIG. 10B.

Referring FIG. 10B, it shows an alternative arrangement of a mounting system where only visual display module (100.1) of VPI system/device is mounted in the opening door (14) of an electrical panel box (13) wherein the VPI circuit module (100.2) is separately mounted/placed inside the panel box (13) such as base of box (13.1) via suitable attachment/placement means and connected with the visual display module (100.1) via cable (21). In this embodiment, the display module (100.1) can be detached from the VPI circuit module (100.2) by disengaging/removing the connecting cable (21) and thus can be removed from the panel box (13) by disengaging the member (15) if required without removing the VPI circuit module (100.2).

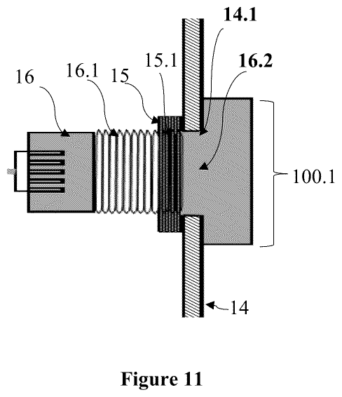

Referring FIG. 11, it shows mounting mechanism for fixing VPI system/device in the door (14) of electrical panel box (13), in one example embodiment, wherein internal thread (15.1) of the holding member (15) engages with the external thread (16.1) of the inner body (16) of VPI display module (100.1). The door (14) at the front side of panel box (13) comprises a hole (14.1) wherein the body (16) is inserted and upon engagement and tightening of the member (15) by screwing engages the base (16.2) of display module (100.1) fits within the hole (14.1) of the door (14) which holds the display module on the door (14) of the panel box (13). The above attachment mechanism is a non-limiting example embodiment and it may also be of different type wherein in place of thread engagement as described above, a suitable snap-fit engagement mechanism may also be used or any suitable engagement mechanism may be used based.

The voltage presence indicator (100) can also include a feature of external dry contacts to trigger any external circuits such as Programmable Logic Controller (PLC)/Supervisory Control and Data Acquisition (SCADA) etc. External dry contacts used in the device with the help of optocouplers triggers external communication with other devices in the electrical system. The relay output of the contacts is enabled by sensing the voltage at the 1^{st} and 2^{nd} group Zener diodes. This feature will allow the maintenance personnel and managers to remotely know the status of the voltage presence indicators without getting into the proximity of the electrical panel.

Another embodiment of the VPI is with a built-in wireless antenna to communicate the device status using Wi-fi/LTE network communication. As shown in FIG. 9B, the VPI display module (100.1) comprises a Wi-Fi module (12) provided in-built for this purpose.

Further, Another embodiment of the VPI can be grouped with current limited test point jacks (11) at the door (14) with either same wires or separate set of wires to measure the voltage using a portable test instrument. This arrangement will allow the operator at the door (14) to measure the quantifiable voltage values of the connected leads of the device in addition to presence indication via LEDs. This approach with current limited voltage measurement at the door by limiting the fault current approximately to 3.5 to 5 mA will eliminate the electric shock and arc flash hazards to the operator.

Advantages of the designed voltage presence indicating circuit (100, 100′, 100″, 100′″, 100″″ and 100′″″) includes the following:
The VPI circuits (100, 100′, 100″, 100′″, 100″″ and 100′″″) are designed to provide monitoring of wide range of stored electrical potentials, from the lowest voltage level of 40 volts to up to 3 kilovolts (line to neutral values) or higher than this.
The VPI circuit is flexible to alter and set the required threshold voltage supply by changing the voltage clipper Zener diodes, and also the circuit can be used in both downstream and upstream of a circuit breaker (CB).
The frequency for which the said VPI circuit (100, 100′, 100″, 100′″, 100″″ and 100′″″) works are 50, 60 and 400 Hz.
The designed VPI circuit (100, 100′, 100″, 100′″, 100″″ and 100′″″) gives visual indication for both AC (three phase and single phase), and DC voltages.
It provides simultaneous indication of presence of voltage of all the three phases of the power line with respect to ground. And, optionally allows for verifying the voltage measurement at the door using portable test instrument.
It can provide continuous visual indication for voltage presence for every line combination in three phase and single phase power lines during maintenance period.
Provides verification of electrical circuit isolation without opening or otherwise accessing the electrical panel.
The total power consumption of the circuit has been reduced to one third as compared with the existing prior art.
The flash rate of the Flasher circuit does not change with respect the applied voltage.

While particular embodiments and applications of the present invention have been illustrated and described, it is to be understood that the invention is not limited to the precise construction and compositions disclosed herein and that various modifications, changes, and variations may be apparent from the foregoing without departing from the scope of the invention as described.

What is claimed is:

1. A voltage presence indicator circuit for monitoring of hazardous electrical potential of a plurality of electrical power input lines of an Alternating Current (AC) or Direct Current (DC) circuit, wherein the voltage presence indicator comprises:
plurality of voltage clipper circuits which comprises first group of voltage clipper circuits and second group of voltage clipper circuits;
plurality of bi-directional current limiter circuits;
plurality of full-bridge rectifier circuits;
plurality of unbalance sensing resistor circuits;
plurality of signal conditioning circuits;
plurality of comparator circuits; and
plurality of flasher circuits.

2. The voltage presence indicator as claimed in claim 1, wherein each of the plurality of the voltage clipper circuits comprises two groups i.e. first group of voltage clipper circuits and second group of voltage clipper circuits wherein, the first group and the second group comprise plurality of zener diodes for clipping of supply voltage and provides the visual indication for presence of hazardous electrical energy potential, above a set threshold voltage value, and wherein the second group of zener diodes is used to provide AC clipped voltage to the said full bridge rectifier circuits present in all the lines L1, L2, L3, N, and GND required for flasher circuits operation.

3. The voltage presence indicator as claimed in claim 1, wherein the plurality of bi-directional current limiter circuits comprises of cross coupled depletion mode MOSFET where the source of each depletion mode MOSFET is coupled to the gate of the opposing MOSFET, and a current limiter resistor is coupled between the sources of the MOSFETs, wherein the cross coupled depletion MOSFET along with current limiting resistor connected electrically in series with the zener diode group of power line wires L1, L2, and L3 to limit the current to a set level even with the application of significant high voltage and regardless of the polarity of the input supply voltage.

4. The voltage presence indicator as claimed in claim 1, wherein the diode based full bridge rectifier circuits receives clipped AC voltage from the second group of zener diodes present in power lines L1, L2, and L3 for providing DC output to the flasher circuits respectively, and the diode based full bridge rectifier circuits receives clipped AC voltage from the second group of zener diodes present in neutral N and ground GND wires respectively for providing DC voltage to the supply pins of comparator circuits for unbalance condition detection.

5. The voltage presence indicator as claimed in claim 1, wherein the unbalance sensing resistor networks are connected in star connection where each resistor is of high impedance and equal in value connected electrically to power line wires, wherein the function of this resistor network is to sense the voltage unbalance condition in the power line and provide vector sum voltage at the junction point to be processed for providing indication of unbalance condition, with the help of flasher circuit respectively.

6. The voltage presence indicator as claimed in claim 1, wherein the signal conditioning circuits comprising of set resistors rectifier diodes, capacitors along with discharge resistors and zener diodes, wherein the set resistor fixes the percentage unbalance voltage value at which the flasher circuit gives indication for unbalance condition, rectifier diode provides DC voltage needed to charge the capacitor, high impedance discharge resistor discharges the parallel connected capacitor thereby reducing the voltage available at the positive input pin of comparator during the condition of restoring the balanced voltage condition from unbalanced condition, and thus making the corresponding flasher extinguished, and wherein the comparator circuit which compares the output of signal conditioning circuit with its internally generated temperature compensated value for detection of unbalance condition.

7. The voltage presence indicator as claimed in claim 1, wherein once the balanced condition restores from unbalanced condition, the high impedance discharge resistors placed across the capacitor present in signal conditioning circuit discharges the corresponding capacitor thereby reducing the voltage available at the positive input pin of comparator as compared to the negative input pin of the comparator, thus making the LEDs of flasher circuit extinguished.

8. The voltage presence indicator as claimed in claim 1, wherein the voltage rating and the number of zener diodes in the circuit are set based on the required value of threshold voltage at which the voltage presence indicator circuit starts giving indication for the presence of electrical energy potential.

9. The voltage presence indicator as claimed in claim 1, wherein in place of the first group and the second group of zener diodes of the voltage clipper circuit in a particular wire of voltage presence indicator circuit, a single rating of zener diode can be selected to perform the function of both the groups—first group and second group zener diodes.

10. The voltage presence indicator as claimed in claim 1, wherein the operation range of the voltage presence indicating circuit can be extended to a particular desired voltage range by modifying the number and/or rating of cross coupled depletion mode devices i.e. depletion MOSFET along with current limiting resistor or by varying the voltage rating of the zener diode of voltage clipper circuits, wherein the lower value of operational voltage range i.e. the detection threshold voltage is configured by varying the voltage ratings of zener diodes of voltage clipper circuit and the higher value is configured by varying the rating and/or the number of cross coupled depletion MOSFET.

11. The voltage presence indicator as claimed in claim 1, wherein the full bridge diode rectifier circuit which receives the clipped AC voltage from the second group of zener diode for the full range of input voltage operation, the zener diodes are connected in common cathode configuration for operation of flasher circuits.

12. The voltage presence indicator as claimed in claim 1, wherein the bidirectional current limiters placed in lines L1, L2 and L3 can be placed suitably in N and GND wire lines making the main circuit symmetrical in terms of placement of components in line wires and neutral wire and ground wire.

13. The voltage presence indicator as claimed in claim 1, wherein the power consumption of voltage presence indicator circuit is optimized by modifying the values of current limiting resistors connected between the source terminals of cross coupled depletion MOSFETs and modifying the resistor values present in unbalance sensing resistor network SR1 and SR2.

14. The voltage presence indicator as claimed in claim 1, wherein an opto-coupler including an opto-coupler input is electrically arranged in place of LEDs of flasher circuit to produce optically isolated signals for isolated remote monitoring.

15. The voltage presence indicator as claimed in claim 1, wherein the illumination intensity of the LEDs of the flasher circuits are not directly proportional to the voltage present in the line i.e. the provided LEDs illuminate with same intensity of light for any value of the operational voltage range present in the line.

16. The voltage presence indicator as claimed in claim 1, wherein the voltage presence indicator is applied to different type of sources i.e. AC as well as DC, different type of phase circuits i.e. single phase circuit or multi phase circuit and to different frequencies.

17. The voltage presence indicator as claimed in claim 1, wherein the electrical circuitry of the voltage presence indicator converts electrical energy potential between the lines in the range of about 40 Volts to about 3000 volt into electrical inputs that drives the flasher circuit consisting of LEDs to produce light output.

18. The voltage presence indicator as claimed in claim 1, wherein the plurality of electrical power input lines of an Alternating Current or Direct Current circuit comprises L1, L2, L3, Neutral and Ground.

19. A method for providing warning of a hazardous electrical voltage on a circuit, the method including: arranging plurality of high impedance bi-directional current path (CL) in which cross coupled depletion MOSFETs offers variable impedance based on the applied input voltage, wherein clipped AC voltage across the common cathode configured zener diode provides clipped AC voltage to the rectifier circuit needed for the operation of flasher circuit which drives LEDs, for the whole operational input voltage range.

20. The method as claimed in claim 19, wherein the method further comprises: limiting the current flowing in a high impedance path irrespective of the magnitude of hazardous electrical voltage.

21. A method for providing detection for unbalance condition in a three-phase circuit, wherein the method comprises: a set of resistor network connected in star connection along with signal conditioning circuits, comparator circuits wherein comparator circuits receives DC voltage for its operation from the full bridge rectifier circuits connected to the second group of zener diodes present in neutral or ground wire.

22. The method as claimed in claim 21, wherein the method further comprises: the set of second group of zener diodes which provides clipped AC voltage to the full bridge rectifier present in the neutral and ground wires are connected electrically to the neutral and ground terminal of the circuit.

23. A voltage presence indicator for providing warning of a hazardous electrical voltage on a circuit powered by a plurality of electrical power input lines, wherein the voltage presence indicator comprises:
a. plurality of high impedance bi-directional current paths where plurality of cross coupled depletion MOSFETs offers variable impedance based on the applied input voltage wherein AC clipped voltage across the common cathode configured zener diode provides constant clipped AC voltage needed for the operation of flasher circuit which drives LEDs, for the whole operational input voltage range;
b. plurality of rectifying paths in which a part of main circuit component current flows through the branch circuit comprising of full bridge rectifier circuits and filter capacitors associated with full bridge rectifier circuits
c. plurality of sensing resistor network comprising equal value and high impedances connected in star fashion wherein each set resistors of the sensing resistor network is communicating with the phase lines to sense the unbalance condition;
d. plurality of signal conditioning circuits which processes the voltage at the junction points of sensing resistor network to provide signal voltage to the comparator to trigger flasher circuit of neutral or ground wire; and
e. plurality of high impedance discharge resistors placed across the capacitor present in signal conditioning circuit which discharges the parallel connected capacitor and helps in reducing the voltage available at the positive input pin of comparator during the condition of restoring the balanced voltage condition from unbalanced condition, thus making the corresponding flasher extinguished;
wherein, the set resistor connected at the junction point of sensing resistor network to tune the percentage unbalance voltage value at which the flasher circuit starts giving indication for unbalance condition.

24. The voltage presence indicator as claimed in claim 23, wherein the main circuit components comprise of voltage clipper circuit which includes zener didoes and bi-directional current limiter circuit which includes depletion MOSFETs.

25. The voltage presence indicator as claimed in claim 23, wherein plurality of electrical power lines comprises a three phase lines, a ground line and a neutral line, the current in the main circuit components flows between three phase lines in normal balanced condition and the current flows through ground and neutral wire in unbalanced condition.

26. The voltage presence indicator as claimed in claim 23, wherein plurality of electrical power lines comprises three phase lines and a ground line, the current in the main circuit components flows between three phase lines in normal balanced condition and the current flows through ground in unbalanced condition.

27. The voltage presence indicator as claimed in claim 23, wherein plurality of electrical power lines comprises a single phase line, a neutral line and a ground line, the current in the main circuit components flows from single phase line to ground and neutral wires.

28. The voltage presence indicator as claimed in claim 23, wherein plurality of electrical power lines comprises two differential AC lines, a neutral line and a ground line, the current in the main circuit components flows from two differential AC lines to ground and neutral.

29. The voltage presence indicator as claimed in claim 23, wherein plurality of electrical power lines comprises two wire DC system, the current in the main circuit components flows from positive power line to negative power line.

30. The voltage presence indicator as claimed in claim 23, wherein plurality of electrical power lines comprises two wires DC system and a ground line, the current in the main circuit components flows from positive and negative power line to ground.

31. The voltage presence indicator as claimed in claim 23, wherein the plurality of electrical power input lines may include both ground and neutral lines or may include any of a ground or neutral line.

32. The voltage presence indicator as claimed in claim 23, wherein the flasher circuits present in each line wire starts giving indication for the presence of voltage in the phase lines, once the input applied voltage is greater than the set threshold voltage.

33. The voltage presence indicator as claimed in claim 1, wherein the said voltage presence indicator can be modified to incorporate solid ON indication by placing the LEDs in series with the cross coupled depletion mode devices along with suitable resistor in series and by eliminating the flasher circuit.

34. The voltage presence indicator as claimed in claim 1, wherein the voltage presence indicator circuitry is placed in an isolation module and kept inside the panel box and only the light indication module is brought to the door of panel box by using a fiber optic cable or other methods, or is placed in a direct attachment without cable connection and isolation module.

35. The voltage presence indicator as claimed in claim 1, wherein the voltage presence indicator comprises a feature of external dry contacts using opto coupler to trigger any external circuits such as Programmable Logic Controller (PLC)/Supervisory Control and Data Acquisition (SCADA).

36. The voltage presence indicator as claimed in claim 1, wherein the voltage presence indicator comprises a current limited test points at the door to measure the voltage using a portable test instrument.

37. The voltage presence indicator as claimed in claim 23, wherein the said voltage presence indicator can be modified to incorporate solid ON indication by placing the LEDs in series with the cross coupled depletion mode devices along with suitable resistor in series and by eliminating the flasher circuit.

38. The voltage presence indicator as claimed in claim 23, wherein the voltage presence indicator circuitry is placed in an isolation module and kept inside the panel box and only the light indication module is brought to the door of panel box by using a fiber optic cable or other methods, or is placed in a direct attachment without cable connection and isolation module.

39. The voltage presence indicator as claimed in claim 23, wherein the voltage presence indicator comprises a feature of external dry contacts using opto coupler to trigger any external circuits such as Programmable Logic Controller (PLC) Supervisory Control and Data Acquisition (SCADA).

40. The voltage presence indicator as claimed in claim 23, wherein the voltage presence indicator comprises a current limited test points at the door to measure the voltage using a portable test instrument.
